(19) United States
(12) Patent Application Publication
(10) Pub. No.: US 2019/0177233 A1
(43) Pub. Date: Jun. 13, 2019

(54) HYDROPHOBIC MATERIALS INCORPORATING RARE EARTH ELEMENTS AND METHODS OF MANUFACTURE

(71) Applicant: Massachusetts Institute of Technology, Cambridge, MA (US)

(72) Inventors: Sami Khan, Cambridge, MA (US); Gisele Azimi, Waltham, MA (US); Adam T. Paxson, Cambridge, MA (US); Kripa K. Varasani, Lexington, MA (US)

(73) Assignee: Massachusetts Institute of Technology, Cambridge, MA (US)

(21) Appl. No.: 16/036,259

(22) Filed: Jul. 16, 2018

Related U.S. Application Data
(63) Continuation of application No. 14/528,799, filed on Oct. 30, 2014, now abandoned.
Application No. 14/528,799 is a continuation-in-part of application No. 13/428,652, filed on Mar. 23, 2012, now abandoned.

(51) Int. Cl. C04B 35/50; C23C 14/06; C23C 14/08; B22F 7/04; B32B 18/00; C23C 14/02

(52) U.S. Cl. CPC C04B 35/50; Y10T 428/12611; C23C 14/08; B22F 7/04; B32B 18/00; C23C 14/025; C04B 2237/76; C04B 2237/704; C04B 2237/582; C04B 2237/58; C04B 2237/38; C04B 2237/366; C04B 2237/361; C04B 2237/36; C04B 2237/346; C04B 2237/343; C04B 2237/34; C04B 2237/125; C04B 2237/123; C04B 2237/122; C04B 2237/121; C04B 2237/12; C04B 2237/08; C04B 2235/658; C04B 2235/604; C04B 2235/3229; C04B 2237/765; Y10T 428/24355; Y10T 428/265; Y02T 50/6765; Y10T 428/24975; C23C 14/06

(57) ABSTRACT

This invention relates generally to an article that includes a base substrate, an intermediate layer including at least one element or compound selected from titanium, chromium, indium, zirconium, tungsten, and titanium nitride on the base substrate, and a hydrophobic coating on the base substrate, wherein the hydrophobic coating includes a rare earth element material (e.g., a rare earth oxide, a rare earth carbide, a rare earth nitride, a rare earth fluoride, and/or a rare earth boride). An exposed surface of the hydrophobic coating has a dynamic contact angle with water of at least about 90 degrees. A method of manufacturing the article includes providing the base substrate and forming an intermediate layer coating on the base substrate (e.g., through sintering or sputtering) and then forming a hydrophobic coating on the intermediate layer (e.g., through sintering or sputtering).

### CROSS-REFERENCE TO RELATED APPLICATION

This Application is a Continuation of U.S. application Ser. No. 14/528,799, filed Oct. 30, 2014, entitled “HYDROPHOBIC MATERIALS INCORPORATING RARE EARTH ELEMENTS AND METHODS OF MANUFACTURE”, which is a Continuation-in-part of U.S. application Ser. No. 13/428,652, filed Mar. 23, 2012, entitled “HYDROPHOBIC MATERIALS INCORPORATING RARE EARTH ELEMENTS AND METHODS OF MANUFACTURE,” each of which are incorporated herein by reference in their entirety.

### STATEMENT OF GOVERNMENT SUPPORT

This invention was made with Government support under Grant No. CBET0952564 awarded by the National Science Foundation. The Government has certain rights in the invention.

### FIELD OF THE INVENTION

This invention relates generally to nonwetting materials and, more particularly, to hydrophobic materials that include rare earth elements. More particularly, in certain embodiments, the invention relates to articles and methods for improving longevity and robustness by improving adhesion of rare earth material coatings using an intermediate layer.

### BACKGROUND OF THE INVENTION

Developing robust hydrophobic surfaces has been a subject of intense research over the past decades. Taking inspiration from natural nonwetting structures, such as lotus leaves, butterfly wings, duck feathers, and water striders, many researchers over the past decades have aimed to decipher some of these peculiar designs to develop novel surfaces that, similar to their natural counterparts, are water repellent. Conventional approaches to designing hydrophobic/superhydrophobic surfaces include creating a rough or textured surface and then modifying the surface by materials with low surface energies, such as polymers or fluoroalkylsilane. These surfaces, although generally nonwetting, face major material-related drawbacks and operational challenges that limit their use in industrial applications. For example, material incompatibility, physical instability, failure under harsh environments, and high cost of fabrication are drawbacks that hinder widespread, large-scale utilization of conventional hydrophobic and superhydrophobic surfaces. Certain hydrophobic and superhydrophobic surfaces are described in Kesong Liu & Lei Jiang, Metallic Surfaces with Special Wettability, Nanoscale, 2011, 3, 825-838.

Recent developments of water-repellent surfaces have pervasively stressed one aspect of hydrophobicity, i.e., designing more complex structures or textures, while overlooking the other aspect, i.e., choosing appropriate materials or chemical compositions, which is equally, if not more, important. For example, the materials used for most hydrophobic surfaces have insufficient mechanical resistance, chemical resistance, and thermal stability for many applications. On the other hand, metals and ceramics are materials of choice for harsh environments, but these materials are generally hydrophilic and may require conform al polymeric hydrophobic coatings or modifiers to render them hydrophobic or superhydrophobic. These modifiers, however, break down or deteriorate in harsh environments. Robust superhydrophobic surfaces have therefore been difficult to realize.

Hydrophobic rare earth material ceramics (e.g., rare earth oxide ceramics) demonstrate excellent water repellency properties and promote desirable dropwise condensation. To reduce costs and maintain structural integrity of process equipment such as pipes, it is favorable to explore the application of rare earth materials (e.g., rare earth oxides) as thin film coatings. However, the longevity of rare earth materials as coatings (e.g., thin film coatings) is a concern, particularly when these coatings are exposed to harsh process environments, such as steam and/or boiling water.

Metals are widely used in industrial applications (e.g., heat exchangers, condensers, etc.) and are particularly prone to issues such as corrosion and scale-formation. Some metals such as copper and nickel are unable to maintain a stable rare earth material film on them when subject to harsh conditions such as high temperature, steam, or and/or boiling water and/or laminar or turbulent fluid flow.

What is needed, then, is a robust, hydrophobic material for use in harsh environments (e.g., where the underlying substrate is exposed to high temperature, steam, and/or boiling water for prolonged time periods) where conventional hydrophobic materials have failed. A particular need exists for hydrophobic materials/coatings that are resistant to high temperatures, steam, boiling water, laminar or turbulent fluid flow, harsh chemicals, and mechanical wear and tear (e.g., abrasion and impact).

### SUMMARY OF THE INVENTION

The articles, devices, and methods presented herein provide robust hydrophobic surfaces with applications across a broad range of industries and technologies. In certain embodiments, novel hydrophobic ceramics comprising a rare earth material (e.g., rare earth oxide) layer and an intermediate adhesion layer are described that demonstrate superior water repellency and robustness and promote dropwise water condensation. In some embodiments, the intermediate layer includes or consists of titanium. In some embodiments, the intermediate layer includes at least one element or compound selected from the list comprising titanium, titanium nitride, chromium, zirconium, indium, and tungsten, and any combination thereof.

These ceramics surpass the state-of-the-art in the field of water repellency in their capability to repel water droplets even from smooth surfaces and their ability to promote dropwise condensation, with remarkably improved heat transfer coefficients. Because these novel ceramic surfaces are robust (i.e., capable of withstanding harsh environments for extended time periods), their deployment may enhance process efficiency, while reducing overall costs and energy consumption in a wide variety of applications that are negatively affected by droplet impingement and filmwise condensation. Examples include, but are not limited to, steam turbine blades, heat exchangers, condensers, hydropower turbines, evaporators, boilers, pipelines, pipes, pumps, and waterproof consumer products.

The articles, devices, and methods described herein offer several advantages over previous approaches in the field of water repellency and superhydrophobic surfaces. Moreover, the articles, devices, and methods described herein offer significant improvements in terms of robustness and longevity, particularly in harsh process conditions (e.g., high temperature, steam, or and/or boiling water, laminar or turbulent fluid flow). For example, no previous coating materials have been reported that are both robust and hydrophobic. The materials and coatings described herein are uniquely capable of repelling water droplets and offering mechanical resistance, chemical inactivity, thermal stability, ease of cleaning, resistance to scale build-up and/or bio-fouling, and other advantages. Further, hydrophobic surfaces based on the materials described herein have the advantage of being more scalable and practical for industrial applications, compared to previous low surface energy organic materials that are physically and thermally unstable and fail under harsh environments.

The articles and materials described herein may be used in a wide variety of industrial applications where hydrophobicity, droplet repellency, robustness, and/or dropwise condensation are desirable. These materials may also offer other industrial implications in development of anti-fouling, anti-fouling, and anti-icing surfaces. For example, these materials may be used in steam turbines, condensers, heat exchangers, aircraft, wind turbines, pipelines, evaporators, boilers, medical devices and implants, and separators.

In one aspect, the invention relates to an article that includes a base substrate, an interlayer, and a hydrophobic layer. The intermediate layer is positioned on the base substrate. The intermediate layer includes at least one element or compound selected from the list comprising titanium, chromium, indium, zirconium, tungsten, and titanium nitride. The hydrophobic layer is positioned on the intermediate layer. The hydrophobic layer des a rare earth element material.

In a further aspect, the invention relates to an article that includes a base substrate, an intermediate layer, and a hydrophobic layer. The intermediate layer is positioned on the base substrate. The intermediate layer includes at least one element or compound that has adhesion properties of titanium or that has adhesion properties similar to those of titanium. The hydrophobic layer is positioned on the intermediate layer. The hydrophobic layer includes a rare earth element material.

in some embodiments, the rare earth element material is or comprises a rare earth oxide. In some embodiments, the rare earth oxide is a lanthanide series rare earth oxide. In some embodiments, the rare earth oxide is or comprises cerium (IV) oxide (“ceria”). In some embodiments, the rare earth oxide is or comprises erbium (IV) oxide (“erbia”).

In some embodiments, the intermediate layer is or comprises titanium. In some embodiments, the intermediate layer is or comprises pure titanium. In some embodiments, the intermediate layer is or comprises a titanium alloy. In some embodiments, the intermediate layer is or comprises doped titanium. In some embodiments, the intermediate layer is or comprises any isotope of titanium, including titanium-46, titanium-47, titanium-48, titanium-49, and/or titanium-50. In some embodiments, the intermediate layer is or comprises titanium nitride. In some embodiments, the intermediate layer is or comprises a titanium halide (or a combination of titanium halides). In some embodiments, the titanium halide includes titanium tetrachloride or titanium (III) chloride.

In some embodiments, an exposed surface of the article has a dynamic contact angle with water of at least about 90 degrees.

In some embodiments, the rare earth element material comprises at least one member selected from the group consisting of a rare earth oxide, a rare earth carbide, a rare earth nitride, a rare earth fluoride, and a rare earth boride. In some embodiments, the rare earth element material comprises a combination of one or more species within one or more of the following categories of compounds: a rare earth oxide, a rare earth carbide, a rare earth nitride, a rare earth fluoride, and a rare earth boride.

In some embodiments, the base substrate is or includes a metal. In some embodiments, the metal comprises at least one species selected from the list comprising copper, steel, nickel, aluminum, and their alloys. In some embodiments, the base substrate is or includes a ceramic. In some embodiments, the ceramic includes at least one species selected from aluminum oxide, aluminum nitride, boron oxide, boron nitride, boron carbide, titanium oxide, titanium nitride, titanium carbide, and any combination thereof. In some embodiments, the ceramic includes a metal oxide (e.g., copper, steel, nickel, or aluminum oxide), a metal carbide (e.g., copper, steel, nickel, or aluminum nitride), or a metal nitride (e.g., copper, steel, nickel, or aluminum nitride). In some embodiments, the base substrate is or includes silicon.

In some embodiments, a thickness of the intermediate layer is at least some embodiments, a thickness of the intermediate layer is between 1-10 nm or between 1-50 nm, between 10400 nm, or between 100 nm-1 micron. In some embodiments, the intermediate layer can have any desired thickness, depending on the application.

In some embodiments, a thickness of the hydrophobic layer is at least 1 nm. In some embodiments, a thickness of the hydrophobic layer is between 1-10 nm or between 1-50 nm, or between 10-300 nm. In some embodiments, the hydrophobic layer can have any desired thickness, depending on the application.

In some embodiments, the hydrophobic layer includes at least about 10 percent by weight of rare earth material. In some embodiments, an exposed surface of the article comprising the hydrophobic layer is textured. In some embodiments, the exposed textured surface comprises multiple-scale surface roughness. In some embodiments, the base substrate is textured.

In some embodiments, the hydrophobic layer comprises at least one of a ceramic, a metal, and a polymer. In some embodiments, the hydrophobic layer is doped with the rare earth element material. In some embodiments, wherein the rare earth element material comprises a first rare earth oxide doped with a second rare earth oxide. In some embodiments, the first rare earth oxide is a light rare earth oxide and the second rare earth oxide is a heavy rare earth oxide. In some embodiments, the heavy rare earth oxide comprises at least one member selected from the group consisting of gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and lutetium oxide (Lu₂O₃). In some embodiments, the light rare earth oxide is cerium oxide (CeO₂) and the heavy rare earth oxide is gadolinium oxide (Gd₂O₃).

In some embodiments, the rare earth element material comprises at least one member selected from the group consisting of scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu). In some embodiments, the rare earth element material comprises at least one member selected from the group consisting of scandium oxide (Sc₂O₃), yttrium oxide (Y₂O₃), lanthanum oxide (La₂O₃), cerium oxide (CeO₂), praseodymium oxide (Pr₆O₁₁), neodymium oxide (Nd₂O₃), samarium oxide (Sm₂O₃), europium oxide (Eu₂O₃), gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and lutetium oxide (Lu₂O₃). In some embodiments, the rare earth element material comprises at least one member selected from the group consisting of cerium carbide (CeC₂), praseodymium carbide (PrC₂), neodymium carbide (NdC₂), samarium carbide (SmC₂), europium carbide (EuC₂), gadolinium carbide (GdC₂), terbium carbide (TbC₂), dysprosium carbide (DyC₂), holmium carbide (HoC₂), erbium carbide (ErC₂), thulium carbide (TmC₂), ytterbium carbide (YbC₂), and lutetium carbide (LuC₂).

In some embodiments, the rare earth element material comprises at least one member selected from the group consisting of cerium nitride (CeN), praseodymium nitride (PrN), neodymium nitride (NdN), samarium nitride (SmN), europium nitride (EuN), gadolinium nitride (GdN), terbium nitride (TbN), dysprosium nitride (DyN), holmium nitride (HoN), erbium nitride (ErN), thulium nitride (TmN), ytterbium nitride (YbN), and lutetium nitride (LuN). In some embodiments, the rare earth element material comprises at least one member selected from the group consisting of cerium fluoride (CeF₃), praseodymium fluoride (PrF₃), neodymium fluoride (NdF₃), samarium fluoride (SmF₃), europium fluoride (EuF₃), gadolinium fluoride (GdF₃), terbium fluoride (TbF₃), dysprosium fluoride (DyF₃), holmium fluoride (HoF₃), erbium fluoride (ErF₃), thulium fluoride (TmF₃), ytterbium fluoride (YbF₃), and lutetium fluoride (LuF₃).

In some embodiments, the rare earth element material comprises at least one member selected from the group consisting of cerium boride (CeB₆), praseodymium boride (PrB₆), neodymium boride (NdB₆), samarium boride (SmB₆), europium boride (EuB₆), gadolinium boride (GdB₆), terbium boride (TbB₆), dysprosium boride (DyB₆), holmium boride (HoB₃), erbium boride (ErB₆), thulium boride (TmB₆), ytterbium boride (YbB₆), and lutetium boride (LuB₆).

In some embodiments, the article is at least one member selected the group consisting of a steam turbine, a condenser, a heat exchanger, a hydro turbine, an aircraft, a wind turbine, a pump, a pipe, a pipeline, an evaporator, a boiler, a medical device, a medical implant, and a separator.

In a further aspect, the invention relates to a method of using the article discussed above, the method including exposing the article to an external phase, wherein a presence of the intermediate layer imparts enhanced resistance to degradation, wherein degradation includes at least one condition selected from the list comprising corrosion, scaling, bio-fouling, liquid water film formation, ice formation, reducing thickness of the hydrophobic layer (e.g., due to undesired degradation/flaking of the hydrophobic layer), pitting, fractures, and/or cracks. In some embodiments, the external phase is steam. In some embodiments, the external phase is boiling water. In some embodiments, the article is a heat exchanger or a condenser.

In another aspect, the invention relates to a method of manufacturing and/or retrofitting a hydrophobic article, including providing a substrate material, depositing an intermediate layer including at least one element or compound selected from the list comprising titanium, chromium, indium, zirconium, tungsten, and titanium nitride on the substrate material, and depositing a hydrophobic layer comprising a rare earth element material on the intermediate layer.

In some embodiments, the method relates to manufacturing and/or retrofitting the hydrophobic article, wherein the hydrophobic article is at least one member selected from the group consisting of a steam turbine, a condenser, a heat exchanger, an aircraft, a wind turbine, a pump, a pipe, a pipeline, an evaporator, a boiler, a medical device, a medical implant, and a separator. in some embodiments, depositing the intermediate layer comprises sputter-depositing, spraying, sintering, or laminating the intermediate layer on the substrate material. In some embodiments, depositing the hydrophobic layer comprises sputter-depositing, spraying, sintering, or laminating the intermediate layer on the intermediate layer.

In a further aspect, the invention relates to an article that includes a base substrate, an intermediate layer, and a hydrophobic layer. The intermediate layer is positioned on the base substrate. The hydrophobic layer is positioned on the intermediate layer. The hydrophobic layer includes a rare earth element material. The intermediate layer allows for a loss of less than 5% of the hydrophobic layer when (i) exposed to steam at 92° C. at a pressure of 75 kPa inside a vacuum condensation chamber for 10 hours or (ii) immersed in boiling water for a period of 10 hours. In some embodiments, the intermediate layer includes at least one element or compound selected from the list comprising titanium, chromium, indium, zirconium, tungsten, and titanium nitride

In one aspect, the invention relates to an article that includes a base substrate and a hydrophobic coating on the base substrate. The hydrophobic coating includes a rare earth element material. An exposed surface of the hydrophobic coating has a dynamic contact angle with water of at least about 90 degrees.

In another aspect, the invention relates to an article containing a rare earth element material. An exposed surface of the article has a dynamic contact angle with water of at least about 90 degrees.

In certain embodiments, the rare earth element material includes a rare earth oxide, a rare earth carbide, a rare earth nitride, a rare earth fluoride, and/or a rare earth boride. In some embodiments, the rare earth element material includes a combination of one or more species within one or more of the following categories of compounds: a rare earth oxide, a rare earth carbide, a rare earth nitride, a rare earth fluoride, and a rare earth boride. For example, the rare earth element material may include a combination of at least two members selected from the group consisting of a first rare earth oxide, a second rare earth oxide, a first rare earth carbide, a second rare earth carbide, a first rare earth nitride, a second rare earth nitride, a first rare earth fluoride, a second rare earth fluoride, a first rare earth boride, and a second rare earth boride. For example, the rare earth element material may include a rare earth oxide. In one embodiment, the article includes a metal and/or a ceramic. A thickness of the coating is preferably from about 100 nm to about 300 nm. In various embodiments, the coating includes a ceramic, a metal, and/or a polymer. The coating may be doped with the rare earth element material. In one embodiment, the exposed surface includes (or is) a textured surface (e.g., multiple-scale surface roughness).

In certain embodiments, the rare earth element material includes a first rare earth oxide doped with a second rare earth oxide. For example, the first rare earth oxide may be a light rare earth oxide, and the second rare earth oxide may be a heavy rare earth oxide. The heavy rare earth oxide may include, for example, gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and/or lutetium oxide (Lu₂O₃). In one embodiment, the light rare earth oxide is cerium oxide (CeO₂) and the heavy rare earth oxide is gadolinium oxide (Gd₂O₃).

In various embodiments, the rare earth element material includes scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and/or lutetium (Lu). In one embodiment, the rare earth element material includes scandium oxide (Sc₂O₃), yttrium oxide (Y₂O₃), lanthanum oxide (La₂O₃), cerium oxide (CeO₂), praseodymium oxide (Pr₆O₁₁), neodymium oxide (Nd₂O₃), samarium oxide (Sm₂O₃), europium oxide (Eu₂O₃), gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and/or lutetium oxide (Lu₂O₃). In some embodiments, the rare earth element material includes cerium carbide (CeC₂), praseodymium carbide (PrC₂), neodymium carbide (NdC₂), samarium carbide (SmC₂), europium carbide (EuC₂), gadolinium carbide (GdC₂), terbium carbide (TbC₂), dysprosium carbide (DyC₂), holmium carbide (HoC₂), erbium carbide (ErC₂), thulium carbide (TmC₂), ytterbium carbide (YbC₂), and/or lutetium carbide (LuC₂). In various embodiments, the rare earth element material includes cerium nitride (CeN), praseodymium nitride (PrN), neodymium nitride (NdN), samarium nitride (SmN), europium nitride (EuN), gadolinium nitride (GdN), terbium nitride (TbN), dysprosium nitride (DyN), holmium nitride (HoN), erbium nitride (ErN), thulium nitride (TmN), ytterbium nitride (YbN), and/or lutetium nitride (LuN). In one embodiment, the rare earth element material includes cerium fluoride (CeF₃), praseodymium fluoride (PrF₃), neodymium fluoride (NdF₃), samarium fluoride (SmF₃), europium fluoride (EuF₃), gadolinium fluoride (GdF₃), terbium fluoride (TbF₃), dysprosium fluoride (DyF₃), holmium fluoride (HoF₃), erbium fluoride (ErF₃), thulium fluoride (TmF₃), ytterbium fluoride (YbF₃), and/or lutetium fluoride (LuF₃).

In certain embodiments, the article is a steam turbine, a condenser, a heat exchanger, an aircraft, a wind turbine, a pipeline, an evaporator, a boiler, a medical device, a medical implant, and/or a separator.

In another aspect, the invention relates to an article having a bulk material doped with a rare earth element ma An exposed surface of the bulk material or the article has a dynamic contact angle with water of at least about 90 degrees.

In certain embodiments, the rare earth element material includes a rare earth oxide, a rare earth carbide, a rare earth nitride, a rare earth fluoride, and/or a rare earth boride. The bulk material may include a ceramic (e.g., a metal oxide, a metal carbide, and/or a metal nitride). For example, the ceramic may include aluminum oxide, aluminum nitride, boron oxide, boron nitride, boron carbide, titanium oxide, titanium nitride, and/or titanium carbide. In one embodiment, the bulk material is a light rare earth oxide doped with a heavy rare earth oxide. In some embodiments, the bulk material is cerium oxide (CeO₂) and the rare earth element material includes gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and/or lutetium oxide (Lu₂O₃).

In various embodiments, the rare earth element material includes scandium (Sc), yttrium (Y), lanthanum (La), cerium (Ce), praseodymium (Pr), neodymium (Nd), samarium (Sm). europium (Eu), gadolinium (Gd), terbium (Tb), dysprosium (Dy), holmium (Ho), erbium (Er), thulium (Tm), ytterbium (Yb), and/or lutetium (Lu). For example, the rare earth element material may include scandium oxide (Sc₂O₃), yttrium oxide (Y₂O₃), lanthanum oxide (La₂O₃), cerium oxide (CeO₂), praseodymium oxide (Pr₆O₁₁), neodymium oxide (Nd₂O₃), samarium oxide (Sm₂O₃), europium oxide (Eu₂O₃), gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and/or lutetium oxide (Lu₂O₃). In some embodiments, the rare earth element material includes cerium carbide (CeC₂), praseodymium carbide (PrC₂), neodymium carbide (NdC₂), samarium carbide (SmC₂), europium carbide (EuC₂), gadolinium carbide (GdC₂), terbium carbide (TbC₂), dysprosium carbide (DyC₂), holmium carbide (HoC₂), erbium carbide (ErC₂), thulium carbide (TmC₂), ytterbium carbide (YbC₂), and/or lutetium carbide (LuC₂). The rare earth element material may include, for example, cerium nitride (CeN), praseodymium nitride (PrN), neodymium nitride (NdN), samarium nitride (SmN), europium nitride (EuN), gadolinium nitride (GdN), terbium nitride (TbN), dysprosium nitride (DyN), holmium nitride (HoN), erbium nitride (ErN), thulium nitride (TmN), ytterbium nitride (YbN), and/or lutetium nitride (LuN). In one embodiment, the rare earth element material includes cerium fluoride (CeF₃), praseodymium fluoride (PrF₃), neodymium fluoride (NdF₃), samarium fluoride (SmF₃), europium fluoride (EuF₃), gadolinium fluoride (GdF₃), terbium fluoride (TbF₃), dysprosium fluoride (DyF₃), holmium fluoride (HoF₃), erbium fluoride (ErF₃), thulium fluoride (TmF₃), ytterbium fluoride (YbF₃), and/or lutetium fluoride (LuF₃).

In certain embodiments, the article is a steam turbine, a condenser, a heat exchanger, an aircraft, a wind turbine, a pipeline, an evaporator, a boiler, a medical device, a medical implant, and/or a separator. In some embodiments, the bulk material contains at least about 10 weight percent rare earth element material, or at least about 25 weight percent rare earth element material.

In another aspect, the invention relates to an article having carbon nanotubes and a hydrophobic coating on the carbon nanotubes. The hydrophobic coating includes a rare earth element material. An exposed surface of the hydrophobic coating has a dynamic contact angle with water of at least about 90 degrees.

In certain embodiments, the rare earth element material includes a rare earth oxide, a rare earth carbide, a rare earth nitride, a rare earth fluoride, and/or a rare earth boride. The coating may be doped with the rare earth element material. The article may be, for example, a steam turbine, a condenser, a heat exchanger, an aircraft, a wind turbine, a pipeline, an evaporator, a boiler, a medical device, a medical implant, and/or a separator.

In another aspect, the invention relates to a method of manufacturing a hydrophobic article. The method includes providing a ceramic material and a rare earth element material, and heating the ceramic material and the rare earth element material to a temperature of at least about 1600° C. The method forms a hydrophobic coating having a dynamic contact angle with water of at least about 90 degrees.

In certain embodiments, the rare earth element material includes a rare earth oxide, a rare earth carbide, a rare earth nitride, a rare earth fluoride, and a rare earth boride. The method may include adding a binder and/or a promoter to the ceramic material and the rare earth element material.

In another aspect, the invention relates to a method of manufacturing a hydrophobic article. The method includes: providing a powder having a rare earth element material; pressing the powder at a pressure greater than 30,000 tsi (tons per square inch) to form a pressed rare earth element material; and sintering the pressed rare earth element material in an argon environment (alternatively, the environment could be air or any other suitable environment). In certain embodiments, the rare earth element material includes a rare earth oxide, a rare earth carbide, a rare earth nitride, a rare earth fluoride, and/or a rare earth boride.

In another aspect, the invention relates to a method of manufacturing a hydrophobic article. The method includes providing a base substrate and forming a coating on the base substrate. The coating includes a rare earth element material.

In certain embodiments, the rare earth element material includes a rare earth oxide, a rare earth carbide, a rare earth nitride, a rare earth fluoride, and/or a rare earth boride. The forming step may include, for example, sputtering and/or sintering and/or spraying.

Elements of embodiments described with respect to a given aspect of the invention may be used in various embodiments of another aspect of the invention. For example, it is contemplated that features of dependent claims depending from independent claim can be used in apparatus and/or methods of any of the other independent claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

While the invention is particularly shown and described herein with reference to specific examples and specific embodiments, it should be understood by those skilled in the art that various changes in form and detail may be made therein without departing from the spirit and scope of the invention.

FIG. 1 is a schematic side view of a droplet resting on a surface during a static, contact angle measurement, according to an illustrative embodiment of the invention.

FIG. 2 is a schematic side view of a droplet on a sloped surface during a dynamic contact angle measurement, according to an illustrative embodiment of the invention.

FIG. 3a is a schematic cross-sectional view of a hydrophobic material having a base substrate and a hydrophobic coating, according to an illustrative embodiment of the invention.

FIG. 3b is a schematic cross-sectional view of a hydrophobic material having a base substrate, an intermediate layer on the base substrate, and a hydrophobic coating on the intermediate layer, according to an illustrative embodiment of the invention.

FIG. 4 is a schematic cross-sectional view of a hydrophobic material having a base substrate and a hydrophobic coating, according to an illustrative embodiment of the invention.

FIG. 5 is a schematic cross-sectional view of a hydrophobic material having a bulk material doped with a rare earth oxide, according to an illustrative embodiment of the invention.

FIG. 6 is a schematic illustration of a method of forming a hydrophobic coating on carbon nanotubes, wherein the hydrophobic coating includes a rare earth oxide, according to an illustrative embodiment of the invention.

FIG. 7 is a schematic side view of water molecules on a hydrophilic aluminum oxide surface, according to an illustrative embodiment of the invention.

FIG. 8 is a schematic side view of water molecules on a hydrophobic rare earth oxide surface, according to an illustrative embodiment of the invention.

FIG. 9 is a photograph of a water droplet on a hydrophilic alumina surface, according to an illustrative embodiment of the invention.

FIG. 10 is a photograph of a water droplet on a hydrophilic silica surface, according to an illustrative embodiment of the invention.

FIG. 11 is a photograph of a water droplet on smooth silicon modified with cerium oxide, according to an illustrative embodiment of the invention.

FIG. 12 is a photograph of a water droplet on nanograss silicon posts modified with cerium oxide, according to an illustrative embodiment of the invention.

FIG. 13 is a collection of photographs of sintered rare earth oxide ceramics, according to an illustrative embodiment of the invention.

FIG. 14 is a plot of measured advancing contact angles of water on sintered ceramics and on hydrophilic alumina and silica, according to an illustrative embodiment of the invention.

FIG. 15 is a plot of calculated total surface free energy and the polar and apolar components of surface free energy, for sintered rare earth oxide ceramics, according to an illustrative embodiment of the invention.

FIG. 16 is a scanning electron microscope image of nanograss silicon post arrays, modified for superhydrophobicity with a thin layer of sputtered ceria, according to an illustrative embodiment of the invention.

FIG. 17 is a photograph of sessile water droplets in a Cassie state (θ=160°) on nanograss silicon posts modified with ceria, according to an illustrative embodiment of the invention.

FIG. 18 includes sequential high-speed photographs of a droplet impinging a. smooth hydrophobic silicon wafer modified with a thin film of a rare earth oxide, according to an illustrative embodiment of the invention.

FIG. 19 includes sequential high-speed photographs of a droplet impinging a nanograss silicon posts modified with a thin layer of ceria, according to an illustrative embodiment of the invention.

FIG. 20 is a photograph of filmwise water condensation on a smooth, hydrophilic silicon surface, according to an illustrative embodiment of the invention.

FIG. 21 is a photograph of dropwise water condensation on a smooth, hydrophobic fluorosilanized silicon wafer, according to an illustrative embodiment of the invention.

FIG. 22 is a photograph of dropwise water condensation on a smooth, hydrophobic film of cerium oxide on a silicon wafer, according to an illustrative embodiment of the invention.

FIG. 23 is a photograph of dropwise water condensation on a smooth, hydrophobic film of erbium oxide on a silicon wafer, according to an illustrative embodiment of the invention.

FIG. 24 is a plot of measured condensation heat flux values for a cerium oxide surface, an erbium oxide surface, a fluorosilanized silicon surface, and a silicon surface, according to an illustrative embodiment of the invention.

FIG. 25 is a photograph of water droplets resting on a hydrophobic cerium oxide surface and a hydrophobic silicon surface, according to an illustrative embodiment of the invention.

FIG. 26 is a photograph of a water droplet on a fluorosilanized surface after the surface had been exposed to 400° C. for two hours, according to an illustrative embodiment of the invention.

FIG. 27 is a photograph of a water droplet on a cerium oxide surface after the surface had been exposed to 400° C. for two hours, according to an illustrative embodiment of the invention.

FIG. 28 is a schematic cross-sectional view of a ceria film deposited on a.

titanium intermediate layer, which is deposited on a silicon substrate, according to an illustrative embodiment of the invention.

FIG. 29 is a series of photographs of sustained dropwise condensation on a ceria film deposited on a titanium intermediate layer, which is deposited on a silicon substrate at different time intervals, according to art illustrative embodiment of the invention.

FIG. 30a is a photograph of a ceria film deposited directly on a substrate (without an intermediate titanium layer) after the ceria film had been exposed to steam for one hour.

FIG. 30b is a photograph of a ceria film deposited on an intermediate titanium layer, which is deposited on a substrate, after the ceria film had been exposed to steam for one hour, according to an illustrative embodiment of the invention.

FIG. 30c is a photograph of a ceria film deposited on a substrate (without an intermediate titanium layer) after the ceria film had been exposed to boiling water for one hour.

FIG. 30d is a photograph of a ceria film deposited on an intermediate titanium layer, which is deposited on a substrate, after the ceria film had been exposed to boiling water for one hour, according to an illustrative embodiment of the invention.

FIG. 31a is a photograph of an erbia (Erbium (III) oxide) film deposited directly on a substrate (without an intermediate titanium layer) after the erbia film had been exposed to steam for one hour.

FIG. 32b is a photograph of an erbia film deposited on an intermediate titanium layer, which is deposited on a substrate, after the erbia film had been exposed to steam for one hour, according to an illustrative embodiment of the invention.

FIG. 32 is a photograph of a ceria film deposited on an intermediate titanium layer, which is deposited on a substrate, after the ceria film had been exposed to steam for ten hours, according to an illustrative embodiment of the invention. As seen in FIG. 32, the ceria film was not damaged during the steam treatment.

### DETAILED DESCRIPTION

It is contemplated that compositions, mixtures, systems, devices, articles, methods, and processes of the claimed invention encompass variations and adaptations developed using information from the embodiments described herein. Adaptation and/or modification of the compositions, mixtures, systems, devices, methods, and processes described herein may be performed by those of ordinary skill in the relevant art

Throughout the description, where articles, compositions, devices and systems are described as having, including, or comprising specific components, or where processes and methods are described as having, including, or comprising specific steps, it is contemplated that, additionally, there are articles, compositions, devices, and systems of the present invention that consist essentially of, or consist of, the recited components, and that there are processes and methods according to the present invention that consist essentially of, or consist of, the recited processing steps.

Similarly, where devices, articles, mixtures, and compositions are described as having, including, or comprising specific compounds and/or materials, it is contemplated that, additionally, there are devices, articles, mixtures, and compositions of the present invention that consist essentially of, or consist of, the recited compounds and/or materials.

It should be understood that the order of steps or order for performing certain actions is immaterial so long as the invention remains operable. Moreover, two or more steps or actions may be conducted simultaneously.

The mention herein of any publication, for example, in the Background section, is not an admission that the publication serves as prior art with respect to any of the claims presented herein. The Background section is presented for purposes of clarity and is not meant as a description of prior art with respect to any claim.

Referring to FIG. 1, in certain embodiments, a static contact angle θ between a liquid and solid is defined as the angle formed by a liquid drop 12 on a solid surface 14 as measured between a tangent at the contact line, where the three phases—solid, liquid, and vapor—meet, and the horizontal. The term “contact angle” usually implies the static contact angle θ since the liquid is merely resting on the solid without any movement.

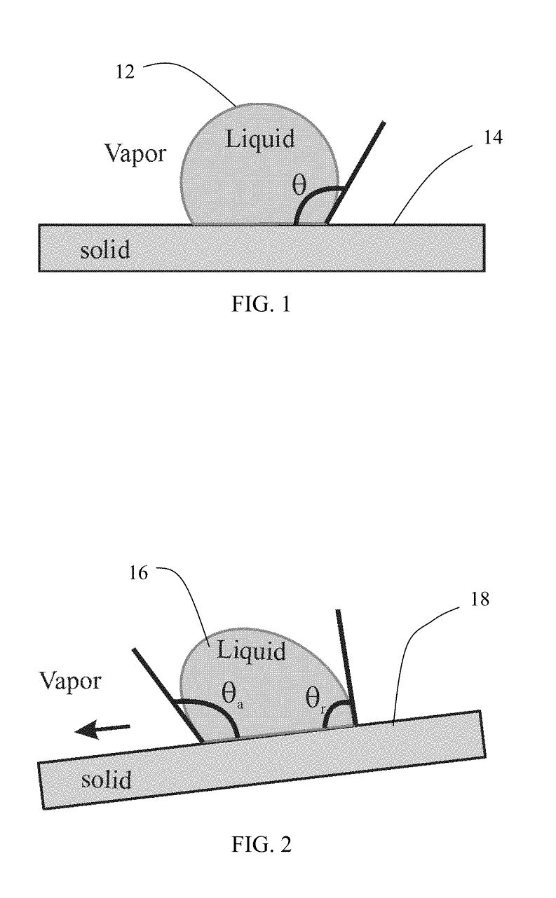

As used herein, dynamic contact angle θ_{d} is a contact angle made by a moving liquid 16 on a solid surface 18. The dynamic contact angle θ_{d} may exist during either advancing or receding movement, as shown in FIG. 2.

In certain embodiments, an intrinsically hydrophobic material (i.e., a material having an intrinsic contact angle with water of at least 90 degrees) exhibits superhydrophobic properties (e.g., a static contact angle with water of at least 120 degrees and a contact angle hysteresis of less than 30 degrees) when it includes a surface texture (e.g., micro-scale or nano-scale). For superhydrophobicity, typically nano-scale surface textures (e.g., pores and/or posts) are preferred.

As used herein, an intrinsic contact angle is a static contact angle formed between a liquid and a perfectly flat, ideal surface. This angle is typically measured with a goniometer. The following publications, which are hereby incorporated by reference herein in their entireties, describe additional methods for measuring the intrinsic contact angle: C. Allain, D. Aussere, and F. Rondelez, J. Colloid interlace Sci., 107, 5 (1985); R. Fondecave, and F. Brochard-Wyart, Macromolecules, 31, 9305 (1998); and A. W. Adamson, Physical Chemistry of Surfaces (New York: John Wiley & Sons, 1976).

As used herein, “multiple-scale surface roughness” is understood to mean physical surface features with two or more characteristic lengths that differ by at least a factor of ten. For example, a surface having multiple-scale surface roughness may include nanoscale and microscale pores and/or protrusions. In certain embodiments, the multiple-scale surface roughness features are produced using mechanical abrasion, self-assembly (e.g., layer by layer assembly or electric field assisted assembly) of nanoparticles, growth or deposition of nanostructures (e.g., carbon nanotubes), and/or lithography.

As used herein, “rare earth element material” is understood to mean a material with at least one component that contains (or is) a rare earth element material. For example, a rare earth element material may contain or be a compound with a rare earth element chemical symbol in its chemical formula.

In certain embodiments, hydrophobic or superhydrophobic materials are achieved through the use of a rare earth element material. In one embodiment, the rare earth element material includes any material having at least one rare earth element. The rare earth element may include, for example, scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and/or lutetium (Lu). In some embodiments, the rare earth element material comprises an elemental form of one or more rare earth elements. In certain embodiments, the rare earth element material includes one or more rare earth compounds.

in various embodiments, the rare earth element material includes or consists of a rare earth oxide, a rare earth carbide, a rare earth nitride, a rare earth fluoride, and/or a rare earth boride. For example, in one embodiment, the rare earth oxide includes scandium oxide (Sc₂O₃), yttrium oxide (Y₂O₃), lanthanum oxide (La₂O₃), cerium oxide (CeO₂), praseodymium oxide (Pr₆O₁₁), neodymium oxide (Nd₂O₃), samarium oxide (Sm₂O₃), europium oxide (Eu₂O₃), gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and/or lutetium oxide (Lu₂O₃). Likewise, the rare earth carbide may include cerium carbide (CeC₂), praseodymium carbide (PrC₂), neodymium carbide (NdC₂), samarium carbide (SmC₂), europium carbide (EuC₂), gadolinium carbide (GdC₂), terbium carbide (TbC₂), dysprosium carbide (DyC₂), holmium carbide (HoC₂), erbium carbide (ErC₂), thulium carbide (TmC₂), ytterbium carbide (YbC₂), and/or lutetium carbide (LuC₂). Possible rare earth nitrides include cerium nitride (CeN), praseodymium nitride (PrN), neodymium nitride (NdN), samarium nitride (SmN), europium nitride (EuN), gadolinium nitride (GdN), terbium nitride (TbN), dysprosium nitride (DyN), holmium nitride (HoN), erbium nitride (ErN), thulium nitride (TmN), ytterbium nitride (YbN), and/or lutetium nitride (LuN). Examples of rare earth fluorides include cerium fluoride (CeF₃), praseodymium fluoride (PrF₃), neodymium fluoride (NdF₃), samarium fluoride (SmF₃), europium fluoride (EuF₃), gadolinium fluoride (GdF₃), terbium fluoride (TbF₃), dysprosium fluoride (DyF₃), holmium fluoride (HoF₃), erbium fluoride (ErF₃), thulium fluoride (TmF₃), ytterbium fluoride (YbF₃), and/or lutetium fluoride (LuF₃).

In certain embodiments, the rare earth element material includes a light rare earth element having an atomic number less than or equal to 63 and/or a heavy rare earth element having an atomic number greater than 63. With respect to rare earth oxides, for example, a light rare earth oxide may include scandium oxide (Sc₂O₃), yttrium oxide (Y₂O₃), lanthanum oxide (La₂O₃), cerium oxide (CeO₂), praseodymium oxide (Pr₆O₁₁), neodymium oxide (Nd₂O₃), samarium oxide (Sm₂O₃), and/or europium oxide (Eu₂O₃). Likewise, in certain embodiments, a heavy rare earth oxide includes gadolinium oxide (Gd₂O₃), terbium oxide (Tb₄O₇), dysprosium oxide (Dy₂O₃), holmium oxide (Ho₂O₃), erbium oxide (Er₂O₃), thulium oxide (Tm₂O₃), ytterbium oxide (Yb₂O₃), and/or lutetium oxide (Lu₂O₃).

In certain embodiments, the rare earth element material includes any possible combination of two or more rare earth element materials. For example, the rare earth element material may include a first rare earth oxide, a first rare earth carbide, a first rare earth nitride, a first rare earth fluoride, and/or a first rare earth boride combined with a. second rare earth oxide, a second rare earth carbide, a second rare earth nitride, a second rare earth fluoride, and/or a second rare earth boride. As another example, the rare earth element material may include two or more rare earth oxides, two or more rare earth carbides, two or more rare earth nitrides, two or more rare earth fluorides, and/or two or more rare earth borides.

In certain embodiments, a chemical formula for the rare earth element material is RΦₓ, where R represents one or more rare earth elements in any molar ratio, Φ represents oxygen, carbon, nitrogen, fluorine, boron, or combinations thereof, in any molar ratio, and x is a number of atoms in the material or compound. Depending on the composition of the rare earth element material, x may or may not be an integer.

In various embodiments, the hydrophobic material includes a rare earth element material combined with a non-rare earth element material (i.e., a material that does not include a rare earth element). For example, the rare earth element material (e.g., a rare earth oxide) may be combined with one or more metals or ceramics, including a metal oxide, a metal nitride, a metal carbide, a metal fluoride, and/or a metal boride.

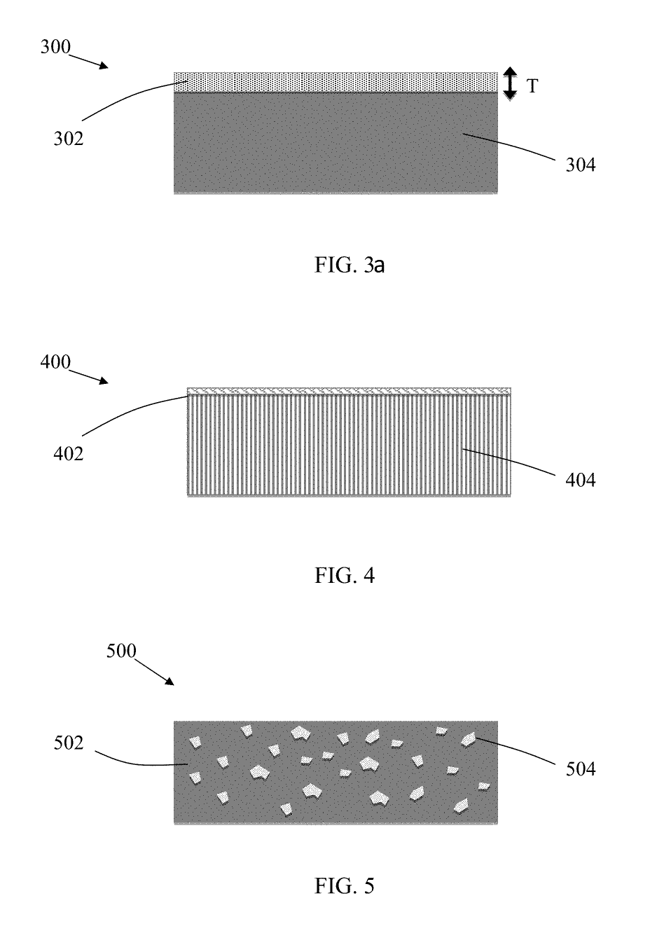

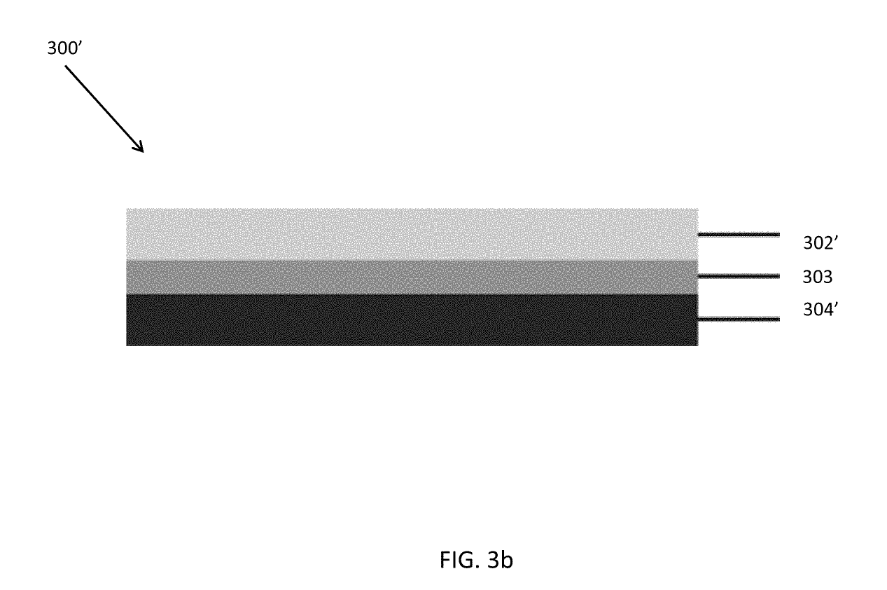

Referring to FIG. 3a, in certain embodiments, a hydrophobic material 300 includes a coating 302 and a base substrate 304. The coating 302 includes or consists of one or more rare earth element materials, such as one or more rare earth oxides. A thickness T of the coating 302 may be, for example, from about 100 nm to about 300 nm. The base substrate 304 includes a metal, a ceramic, and/or a polymer. For example, the base substrate 304 may include a metal and/or a transition metal and/or their alloys, e.g., aluminum, copper, titanium, nickel, and/or steel. The base substrate 304 may include, for example, a ceramic such as a metal oxide, a metal carbide, and/or a metal nitride, Examples of ceramic materials include aluminum oxide, aluminum nitride, boron oxide, boron nitride, boron carbide, titanium oxide, titanium nitride, and/or titanium carbide. A method of producing the hydrophobic material includes providing the base substrate 304. and applying the coating onto the base substrate 304 using, for example, sputtering, sintering, laminating, and/or spraying.

In some embodiments, an intermediate adhesion or bonding layer is disposed between the coating 302 and the base substrate 304 (e.g., as shown in FIG. 3b). The bonding layer may provide improved adhesion between the coating 302 and the base substrate 304. The bonding or adhesion layer may include, for example, a metal, an intermetallic, an alloy, and/or a ceramic. Specific examples include indium (In), titanium (Ti), titanium nitride (TiN), chromium nitride (CrN), nickel aluminide (e.g., NiAl), MCrAlY, platinum, nickel, and/or aluminum. In some embodiments, the bonding or adhesion layer includes an element or compound that has adhesion properties similar to that of pure titanium.

Referring to FIG. 3b, in certain embodiments, an article 300′ includes a top layer 302′, an intermediate layer 303, and a base layer 304′. The top layer 302′ is positioned on top of and in direct contact with the intermediate layer 303′. The intermediate layer 303 is positioned on top of and in direct contact with the base layer 304′. In some embodiments, the base layer 304′ is textured. In some embodiments, the intermediate layer 303 is textured. In some embodiments, the top layer 302′ is textured.

The top layer 302′ (hydrophobic layer) includes or consists of one or more rare earth element materials, such as one or more rare earth oxides. In some embodiments, the rare earth material is present in the top layer 302′ in an amount of at least about 10 weight %, at least about 15 weight %, at least about 20 weight %, at least about 25 weight %, at least about 30 weight %, at least about 35 weight %. In some embodiments, the rare earth material o a combination of rare earth materials) is present in the top layer 302′ in an amount of between 10-20 weight %, 15-30 weight %, 30-50 weight %. The composition of the top layer 302′ may be the same as or different than the coating 302 of FIG. 3a. In some embodiments, the top layer 302′ includes a rare earth material and at least one transition element or an inner transition metal. In some embodiments, the top layer 302′ includes a rare earth material and at least one element whose atom has a partially filled d sub-shell, or which can give rise to cations with an incomplete d sub-shell. In some embodiments, the top layer 302′ includes a rare earth material and any element in the d-block (groups 3-12) of the Periodic Table.

in some embodiments, the top layer 302′ has a thickness between about 100 nm to about 300 nm. In some embodiments, the top layer 302′ has a thickness between about 1 nm and about 10 nm or between about 5 nm and 10 nm, or between about 10 nm and about 50 nm, or between about 50 nm and about 100 nm. In some embodiments, the top layer 302′ has a thickness between about 100 nm to about 1 micron. In some embodiments, the top layer 302′ has a thickness between about 1 nm-1 micron, 1-10 nm, 5-10 nm, 5-50 nm, 50-100 nm, 80-100 nm, 100-200 nm, 150-300 nm, 250-500 nm, 500 nm-1 micron. In some embodiments, the top layer 302′ has a thickness of at least 1 nm, at least 5 nm, at least 10 nm, at least 50 nm, at least 100 nm, at least 200 nm, at least 300 nm, at least 400 nm, at least 500 nm, at least 600 nm, at least 750 nm, or at least 1 micron.

In some embodiments, the base substrate 304′ includes a metal, a ceramic, and/or a polymer. In some embodiments, the base substrate 304′ includes silicon. In some embodiments, the composition and properties of the base substrate 304′ is the same as that of the base substrate 304 of FIG. 3a. For example, in some embodiments the base substrate 304′ includes a metal and/or a transition metal and/or their alloys, e.g., aluminum, copper, titanium, nickel, and/or steel. In some embodiments, the base substrate 304′ includes, for example, a ceramic such as a metal oxide, a metal carbide, and/or a metal nitride. Examples of ceramic materials include, but are not limited to, aluminum oxide, aluminum nitride, boron oxide, boron nitride, boron carbide, titanium oxide, titanium nitride, and/or titanium carbide.

In some embodiments, the intermediate layer 303 has a thickness between about 10 nm and about 100 nm. In some embodiments, the intermediate layer 303 has a thickness between about 1 nm and about 10 nm. In some embodiments, the intermediate layer 303 has a thickness between about 50 nm and about 300 nm. In some embodiments, the intermediate layer 303 has a thickness between about 50 nm and about 1 micron. In some embodiments, the intermediate layer 303 has a thickness between 1 nm-1 micron, 1-5 nm, 1-10 nm, 5-10 nm, 10-20 nm, 10-30 nm, 20-40 nm, 40-50 nm, 50-100 nm, 50-150 nm, 100-200 nm, 100-300 nm, 100-500 nm, 500 nm-1 micron. In some embodiments, the intermediate layer 303 has a thickness of at least 1 nm, at least 5 nm, at least 10 nm, at least 50 nm, at least 100 nm, at least 200 nm, at least 300 nm, at least 400 nm, at least 500 nm, at least 600 nm, at least 750 nm, or at least 1 micron.

In some embodiments, the thickness of the intermediate layer 303 is uniform In some embodiments, the thickness of the intermediate layer 303 is non-uniform. In some embodiments, the intermediate layer 303 is sputter-deposited on the base substrate 304′. In some embodiments, the intermediate layer 303 is deposited on top of the base substrate 304′ via any suitable method or a combination of methods, for example, sputtering, chemical vapor deposition, pulsed laser deposition, cathodic arc deposition, atomic layer deposition, electron beam evaporation, in-situ chemical growth, molecular beam epitaxy, electrospray deposition, spin coating, sintering, laminating, and/or spraying.

In some embodiments, the intermediate layer is or includes at least one element or compound selected from the list comprising titanium, titanium nitride, titanium halide (including titanium tetrachloride and titanium (III) chloride), chromium, indium, zirconium, or tungsten. In some embodiments, the intermediate layer is or includes chromium. In some embodiments, the intermediate layer is or includes indium. In some embodiments, the intermediate layer is or includes zirconium. In some embodiments, the intermediate layer is or includes tungsten.

In some embodiments, the intermediate layer is or includes at least one element or compound that has adhesion properties similar to that of titanium, In some embodiments, the adhesion properties are such that when a layer of titanium is coated on top of a substrate (e.g., silicon substrate) and a hydrophobic layer including a rare earth element (e.g., rare earth oxide, e.g., ceria) is coated on top of the intermediate layer, and the hydrophobic layer is continuously exposed to harsh environmental conditions for a 10 hour period of time, (e.g., steam as discussed in experiments below and/or boiling water), the loss of the hydrophobic layer is less than 20 percent by weight of the hydrophobic layer, less than 15 percent by weight of the hydrophobic layer, less than 10 percent by weight of the hydrophobic layer, less than 5 percent by weight of the hydrophobic layer, less than 3 percent by weight of the hydrophobic layer, less than 2 percent by weight of the hydrophobic layer, or less than 1 percent by weight of the hydrophobic layer.

In some embodiments, the intermediate layer 303 is or includes titanium. In some embodiments, the intermediate layer consists of pure titanium. In some embodiments, the intermediate layer 303 includes pure titanium. In some embodiments, the intermediate layer 303 includes any known isotope of titanium, including titanium-46, titanium-47, titanium-48, titanium-49, and titanium-50. In some embodiments, the titanium is a titanium alloy. In some embodiments, the titanium is elemental, an alloy, or another form other than titanium oxide. In some embodiments, the intermediate layer is or includes titanium nitride. In some embodiments, the intermediate layer includes titanium and at least one additional material or a combination of two or more additional materials. In some embodiments, the intermediate layer 303 includes titanium and at least one other material selected from the list comprising a metal, an intermetallic, an alloy, and/or a ceramic. In some embodiments, the titanium in the intermediate layer 303 includes a dopant.

In some embodiments, the titanium is present in the intermediate layer 303 in a concentration of between 0.1 weight percent and 100 weight percent. In some embodiments, the titanium (e.g., elemental titanium) is present in the intermediate layer in a concentration of at least 0.1 weight percent, at least 0.5 weight percent, at least 1 weight percent, at least 5 weight percent, at least 10 weight percent, at least 15 weight percent, at least 20 weight percent, at least 25 weight percent, at least 30 weight percent, at least 40 weight percent, at least 50 weight percent, at least 60 weight percent, at least 75 weight percent, at least 80 weight percent, at least 85 weight percent, at least 90 weight percent, at least 95 weight percent, or at least 99 weight percent. In some embodiments, the intermediate layer 303 includes a titanium alloy. In some embodiments, the titanium alloy is an alpha alloy, a near-alpha alloy, an alpha and beta alloy, or a beta alloy. In some embodiments, the titanium alloy includes at least one or a combination of elements selected from the list comprising aluminum, gallium, germanium, carbon, oxygen, and nitrogen. In some embodiments, the titanium alloy includes at least one or a combination of elements selected from molybdenum, vanadium, tantalum, niobium, iron, cobalt, copper, silicon, chromium, manganese, and nickel. In some embodiments, the titanium alloy is a Ti6Al4V alloy. In some embodiments, the titanium is Grade 1 (as indicated by ASME SB-265).

In some embodiments, the hydrophobic layer 302′ is deposited on the intermediate layer 303. In some embodiments, the hydrophobic layer 302′ of FIG. 3b is sputter-deposited on the intermediate layer 303. In some embodiments, the hydrophobic layer 302′ is deposited on top of the intermediate layer 303 via any suitable method or a combination of methods, for example, sputtering, chemical vapor deposition, pulsed laser deposition, cathodic arc deposition, atomic layer deposition, electron beam evaporation, in-situ chemical growth, molecular beam epitaxy, electrospray deposition, spin coating, sintering, laminating, and/or spraying.

As illustrated in the experiments below, in some embodiments, the presence of the intermediate layer 303 provides improvements to the article 300′ as compared to similar articles that do not include the intermediate layer 303. In some embodiments, the presence of the intermediate layer 303 imparts improved resilience and/or longevity characteristics to the article 300′. In some embodiments, the presence of the intermediate layer 303 allows for the top layer 302′ to remain stably adhered to the substrate (e.g., not degrade or flake off) under harsh and destructive conditions, including exposure of the top layer 302′ to high temperature, steam, and/or boiling water. In some embodiments, the presence of the intermediate layer 303 allows the top layer 302′ to not degrade or flake off, such that less than 5% of the hydrophobic layer is lost over a period of 10 hours of continued exposure to steam or boiling water.

In some embodiments, the presence of the intermediate layer 303 including titanium allows the top layer 302′ including a rare earth element material to stably adhere and to remain stably adhered to the substrate (via the intermediate layer 303) even under harsh conditions, including prolonged exposure to steam and/or boiling water. In some embodiments, the prolonged exposure is for a period of 1 hour, 2 hours, 2-5 hours, 1-10 hours, 5-10 hours, 1-12 hours, 12-24 hours, 1-5 days, 1-7 days, or another suitable time depending on the nature of the article 300′ and/or the exposure conditions. In some embodiments, the presence of the intermediate layer 303 imparts resilience and/or longevity during an entire useful life of the article 300′.

In some embodiments, in the presence of the intermediate layer 303 including titanium, the top layer 302′ (e.g., hydrophobic rare earth oxide coating layer) significantly outperforms other hydrophobic materials such as organic silanes that would normally degrade relatively quickly in the presence of harsh process environments (e.g., steam, boiling water, etc.). In turn, this significantly reduces clean-up, maintenance, and other operating costs; moreover, this makes the article 300′ more environmentally friendly.

In some embodiments, the article 300′ is an article used in the hydropower industry and/or marine applications. In these applications, the presence of the intermediate layer 303 including titanium is the top layer 302′ (e.g., hydrophobic rare earth oxide coating layer) to remain stably adhered to the base substrate, to maintain integrity, and it promotes corrosion resistance for an extended period of time (e.g., several hours, several days, several weeks, several months, or during a useful life of the article).

In some embodiments, the article 300′ has anti-scaling and/ bio-fouling resistant properties due to the low surface energy of the top layer 302′ (e ,g., hydrophobic rare earth oxide coating layer). The presence of the intermediate layer 303 imparts improved anti-scaling and/or bio-fouling resistant properties to the article 300′.

The presence of the intermediate layer 303 imparts improved robustness and longevity to the article 300′, which significantly mitigates, reduces, or minimizes the environmental damage commonly associated with degradation of process equipment and coatings due to corrosion and/or harsh process conditions.

The article 300′ may be used in a wide variety of industries and applications. In some embodiments, the article 300′ is an article employed in hydropower conveyance structures. In some embodiments, the presence of a composite of the intermediate layer 303 and the top layer 302′ (e.g., rare earth oxide layer) minimizes contact time with water and thereby greatly enhances longevity of hydropower water conveyance structures such as pipes, pumps, and heat exchangers. Long-term environmental impact that is commonly associated with degradation of these components is also minimized due to the presence of the intermediate layer 303.

In some embodiments, the article 300′ is used in an energy manufacturing environment. In some embodiments, using the top layer 302′ (e.g., rare earth oxide layer) coated on top of the intermediate layer 303 (e.g., titanium layer) allows steam turbine manufacturers to achieve higher power outputs by reducing efficiency losses that are caused by water droplets, entrained in steam, impinging on turbine blacks and forming liquid films. Moreover, industries that rely on condensation heat transfer as an integral part can attain remarkable economic incentives by utilizing the composite coatings (e.g., top layer (e.g., hydrophobic rare earth material layer) coated on top of an intermediate layer (e.g., titanium layer)) discussed herein in manufacturing condensers and heat exchangers. In some embodiments, existing condensers and heat exchangers can be retrofitted to include the coatings discussed herein—e.g., to include the intermediate layer (e.g., titanium layer) and the top layer (e.g., rare earth material layer). In some embodiments, an existing heat exchanger is coated with an intermediate layer (e.g., titanium layer) via a suitable method. (e.g., sputter deposition).

In some embodiments, the article 300′ is used in power generation and desalination plants. The presence of the intermediate layer 303 (e.g., titanium layer) allows for achieving higher heat transfer coefficients (e.g., up to 14 times higher than similar articles that do not include an intermediate layer 303 (e.g., titanium layer)) by promoting dropwise condensation over the film condensation.

In some embodiments, the article 300′ is an aircraft engine or part or a wind turbine. In some embodiments, the aircraft engine (or a part or portion thereof) wind turbine (or a part or portion thereof) is coated with an intermediate layer (e.g., titanium layer) using a suitable coating or deposition method (e.g., sputter deposition). A top layer (e.g., hydrophobic rare earth element layer) is applied via a suitable method on top of the intermediate layer. In some embodiments, existing aircraft engine or a wind turbine can be retrofitted to include the coatings discussed above. In some embodiments, using aircraft or wind turbines made or retrofitted with composites including a top layer (e.g., hydrophobic rare earth material layer) coated on top of the intermediate layer (e.g., titanium layer) offer a number of advantages including preventing liquid film formation on aircraft wings and wind turbines due to superior water repellency characteristics of these coatings. Moreover, the presence of the intermediate layer including titanium imparts improved robustness properties, such that the superior water repellency characteristics are present for extended time periods (e.g., useful life of the articles). Consequently, utilizing such coatings prevents aircraft surfaces from freezing and subsequent degraded aerodynamic performance.

In some embodiments, the article 300′ is used in bio-fouling applications. Due to their low surface energy, rare earth material coatings (e.g., rare earth oxide coating) resist bio-fouling bio-films in a wide variety of equipment. The presence of the intermediate layer 303 imparts stability and longevity to the top layer 302′ rare earth material coating layer), thereby presenting significant economic savings for industries that suffer from damage induced by bio-fouling.

In some embodiments, the article 300′ is an evaporator or a boiler. Evaporators and boilers are heat transfer devices that con from liquid to vapor phase.

Similar condensers, large inefficiencies occur at the fluid-surface interfaces, due to the formation of vapor films, and consequent thermal resistance to heat transfer. In some embodiments, an exposed surface of an evaporator or a boiler is coated with an intermediate layer (e.g., titanium layer), and a top layer (e.g., rare earth material layer) is applied on top of the intermediate layer via a suitable method. The presence of the top layer (e.g., rare earth oxide layer) coated on the intermediate layer (e.g., titanium layer) enhances boiling performance not only due to the hydrophobicity of rare earth oxides but also due to the longevity potential offered by the intermediate layer (e.g., titanium layer) In some embodiments, evaporators and boilers may be retrofitted to include the intermediate layer and the top layer or the evaporators and boilers may be manufactured with the intermediate and top layers.

In some embodiments, the article 300′ is used in catalytic applications. The presence of the top layer (e.g., rare earth oxide layer) coated on top of the intermediate layer (e.g., titanium layer) enhanced longevity of any catalytic application of rare earth oxides, including, but not limited to, in the catalytic converter of automobiles.

In some embodiments, the article 300′ is used in an industry with scaling issues. In some embodiments, the article 300′ is used in deep sea oil and gas operations.

Referring to FIG. 4, in certain embodiments, a hydrophobic material 400 includes a coating 402 and a base substrate 404 that each contain a rare earth element material (e.g., a rare earth oxide), although the concentration of rare earth element material is higher in the coating 402 than in the base substrate 404. For example, the coating 402 may include a weight percent of the rare earth element material that is about an order of magnitude greater than the weight percent of the rare earth element material in the base substrate 404. In various embodiments, the weight percent of rare earth element material in the coating 402 is at least about 10 percent, at least about 25 percent or at least about 50 percent. A thickness of the coating 402 may be, for example, from about 100 nm to about 500 nm.

The base substrate 404 may include, for example, a ceramic, such as a metal oxide, a metal carbide, and/or a metal nitride. Specific examples of ceramics include aluminum oxide, aluminum nitride, boron oxide, boron nitride, boron carbide, titanium oxide, titanium nitride, and titanium carbide. In various embodiments, a weight percentage of rare earth element material (e.g., rare earth oxide) in the base substrate 404 is less than about 1 percent, less than about 10 percent, or less than about 25 percent. A weight percentage of the rare earth element material in the base substrate 404 may be substantially uniform, or the weight percentage may be higher near the coating 402 than away from the coating 402.

A method of forming the base substrate 404 and the coating 402 includes exposing the material components (e.g., the rare earth element material and a ceramic) to high temperatures (e.g., from about 1200° C. to about 1600° C.) in a furnace, under atmospheric pressures. Under these conditions, the molecules of the rare earth element material (e.g., a rare earth oxide) migrate toward the surface of the material and accumulate to form the coating 402. At the same time, the ceramic material moves away from the surface to form the base substrate 404. To facilitate the desired migration of rare earth element material and ceramic, a binder or promoter (e.g., polyvinyl alcohol and/or polystyrene) may be added to the material components before they are placed in the furnace.

Referring to FIG. 5, in certain embodiments, a hydrophobic material 500 includes a bulk material 502 that is impregnated or doped with a rare earth element material, such as a rare earth oxide 504. In one embodiment, the hydrophobic material 500 includes at least about 10 percent, at least about 25 percent, or at least about 50 percent rare earth element material, by weight. For example, the weight percentage of rare earth element material in the hydrophobic material 500 may be from about 10 percent to about 25 percent, from about 25 percent to about 50 percent, from about 50 percent to about 75 percent, or from about 75 percent to about 99 percent.

The bulk material 502 includes a metal, a ceramic, and/or a polymer. For example, the bulk material 502 may include a metal and/or a transition metal and/or their alloys, e.g., aluminum, copper, titanium, and/or steel. The bulk material 502 may include, for example, a ceramic such as a metal oxide, a metal carbide, and/or a metal nitride. Examples of ceramic materials include aluminum oxide, aluminum nitride, boron oxide, boron nitride, boron carbide, titanium oxide, titanium nitride, and/or titanium carbide. in certain embodiments, the bulk material 502 is a coating. For example, the bulk material 502 with the doped rare earth element material may be coated onto a ceramic, metallic, or polymeric substrate, such as a tube, a block, or a turbine blade,

Typically, in its impregnated or doped form, the rare earth element material (e.g., a rare earth oxide) is distributed within the bulk material 502 as individual molecules. Alternatively, the rare earth element material may be dispersed within the bulk material 502 as small micro or nano-sized particles. In certain embodiments, the rare earth element material reacts with another compound (e.g., a ceramic compound) in the bulk material 502 to form a new compound, For example, lanthanum oxide (La₂O₃) may react with boron oxide (B₂O₃) to form LaBO₄.

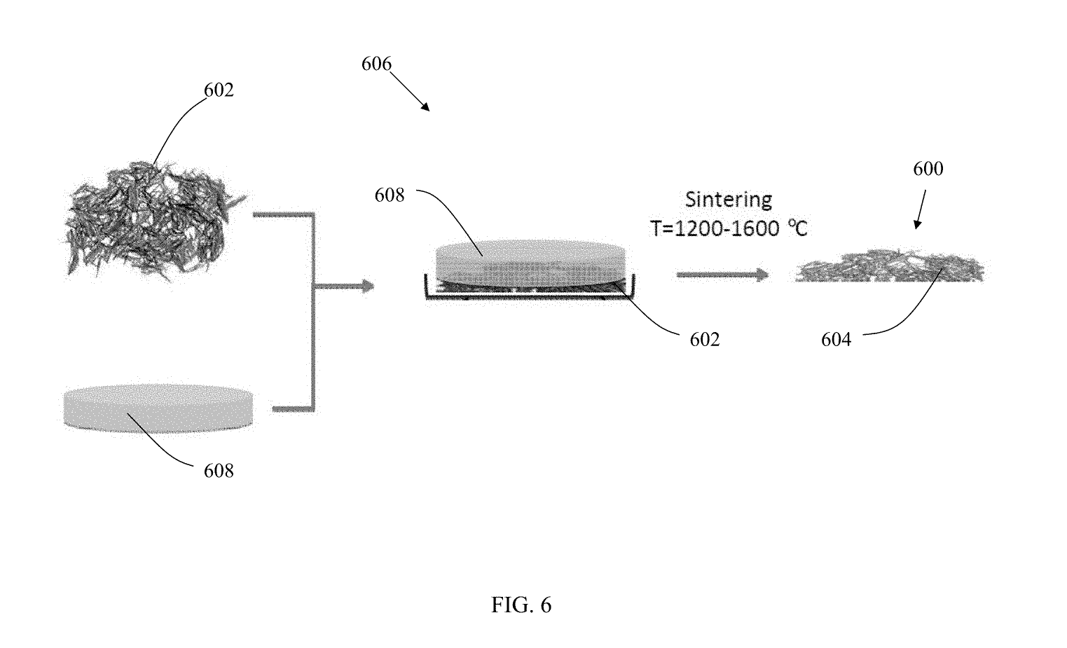

Referring to FIG. 6, in certain embodiments, a hydrophobic material 600 includes carbon nanotubes 602 and a coating 604 having a rare earth element material (e.g., a rare earth oxide). A method 606 of producing the hydrophobic material 600 includes disposing a rare earth element material 608 (or a material doped with the rare earth element material) over the carbon nanotubes 602 and sintering the rare earth element material 608 onto the carbon nanotubes 602. The sintering may be performed in an alumina crucible and/or take place at a temperature from about 1200° C. to about 1600° C. In alternative embodiments, the coating 604 is produced by spraying or sputtering. Due to surface textures in the resulting hydrophobic material 600, the hydrophobic material 600 with the carbon nanotubes 602 may exhibit superhydrophobic qualities.

In certain embodiments, a rare earth element material is formed by dry pressing a powder of the rare earth dement material to form a pressed rare earth element material (e.g., a pressed rare earth oxide). The pressing may occur, for example, at a pressure between 30,000 and 50,000 tsi (tons/in²) (e.g., in a cylindrical steel press mold), without use of any binding agents or additives. The pressed rare earth element material may then be sintered (e.g., inside a tube furnace under argon environment). The sintering temperature may be based on the melting point of the rare earth element material. For example, the sintering temperature may be from about 60 percent to about 80 percent of the melting point of the rare earth element material. In one embodiment, the sintering temperature is from about 1400° C. to about 1650° C.

In certain embodiments, an article is provided that includes one or more of the hydrophobic materials described herein. The article may have any shape or size and may be used for any purpose. For example, the article may be substantially flat (e.g., a block or a plate), curved (e.g., a sphere, a cylinder, or a tube), small (e.g., a medical device), or large (e.g., an airplane wing or a wind turbine blade). In a typical embodiment, the article is used in an application there a robust hydrophobic surface is desired. The article may be, for example, a steam turbine, a condenser, a heat exchanger, an aircraft, a wind turbine, a pipeline (e.g., an oil or gas pipeline), an evaporator, a boiler, a medical device or implant, and/or a separator.

The hydrophobic materials described herein offer vast industrial implications for improving efficiency and reducing overall cost and energy consumption in various industrial applications where hydrophobicity, droplet repellency, and/or dropwise condensation are desirable. The hydrophobic materials also have applications as anti-fouling and anti-icing surfaces.

For example, the hydrophobic materials described herein may be used by steam turbine manufacturers to achieve higher power outputs by reducing efficiency losses caused by water droplets, entrained in steam, impinging on turbine blades and forming liquid films. Moreover, industries that rely on condensation heat transfer may attain remarkable economic improvements by utilizing the hydrophobic materials in condensers and heat exchangers. Specific industries include power generation and water desalination. In certain applications, such industries may achieve higher heat transfer coefficients (up to one order of magnitude) by promoting dropwise condensation over filmwise condensation.

In various embodiments, the hydrophobic materials described herein are used in aircraft and/or wind turbines. For example, surface designs made using the hydrophobic materials may prevent liquid water film formation on aircraft wings and wind turbine blades, due to the superior water repellency attribute of these materials. In aircraft applications, the materials may prevent aircraft surfaces from freezing, thereby enhancing safety and improving aerodynamic performance.

The hydrophobic surfaces also have applications in industries where scaling problems are encountered. Scaling is a persistent problem in various industrial processes, including oil and gas flow through pipelines, desalination, steam generation, and hydrometallurgy. Considering the low surface free energy of the hydrophobic materials, articles that include these materials may be engineered to provide anti-fouling. Such designs not only reduce costs of chemical and thermal treatment for scale inhibition and removal, they also have implications for efficiency, lifetime enhancement, and process reliability improvement the respective processes.

In certain embodiments, the hydrophobic materials are used in deep sea oil and gas industries. For example, the hydrophobic materials may be utilized to provide hydrate-phobic surfaces that prevent hydrate-formation. Such applications may enhance flow assurance and prevent catastrophic failures in deep-sea oil and gas operations.

The hydrophobic materials may also be used in evaporators and/or boilers. Evaporators and boilers are heat transfer devices that convert a fluid from a liquid phase to a vapor phase. Similar condensers, large inefficiencies may occur at the fluid-surface interfaces, due to the formation of vapor films and associated heat transfer resistance. In one embodiment, the hydrophobic materials are used to overcome the fundamental limitations of boiling. For example, these materials may be used in applications in which rare earth oxides act as boiling nucleation sites, thereby resulting in increased rewetting of the surface during boiling and prevention of vapor film formation.

The hydrophobic materials described herein also have applications in medical devices and/or implants. For example, these materials may be used in joint replacement surgery or other types of surgery, tubing (e.g., catheters), dialysis, and any other medical application in which robust hydrophobic materials are desired.

The hydrophobic materials described herein also have applications in separation devices. In one embodiment, these materials are used to separate oil-water mixtures.

Rare earth elements have a peculiar electronic configuration, characterized by the successive addition of electrons to the inner 4f orbitals across the lanthanides row. Because the deep-lying 4f electrons are well shielded from the chemical surrounding by eight electrons of the (5s²p⁶) outer shell, they do not take part in chemical bonding. This unique electronic structure accounts for relatively low standard atomization enthalpy and ionization potential of the rare earths, a property which makes them highly active reducing elements with comparatively low electronegativities, ranging from 1.01 (Eu) to 1.14 (Lu), similar to that of some alkali earth metals, e.g., calcium (1.04). This implies rare earths react readily with the oxygen in the natural environment to form ceramic oxides (mostly sesquioxide, R₂O₃). Similar peculiarities may explain other unique properties of the rare earths and their compounds, including outstanding paramagnetic and luminescent attributes, that make them superior to other transition elements in the Periodic Table, even the actinides with a comparable 5f configuration.

Despite the exceptional properties and potential advantages of the rare earth oxides, the wetting properties of these materials, however, have been left unexplored due to the belief that most metal oxides are hydrophilic. The reason for such belief arises from the fact that common metal oxides demonstrate significant polar component of surface free energy due to the large number of acid and base sites at their surfaces. These polar (i.e., acid and base) sites originate from unsaturated metal atoms that could accept a pair of electrons, acting as Lewis acid sites, and oxygen atoms, capable of donating a pair of electrons and acting as Lewis base sites, when in contact with wetting liquids.

It has been shown through molecular dynamics (MD) simulations that the surface chemistry and surface polarity are likely in direct correspondence with the orientation of water molecules at the interface, and therefore each defines the hydrophobicity or hydrophilicity of the surface. In the case of common metal oxides such as Al₂O₃, polar component of surface free energy becomes significant due to the large number of acid and base sites at their surfaces. These polar sites may accept a pair of electrons, acting as Lewis acid sites, or donate a pair of electrons and acting as Lewis base sites, when in contact with wetting liquids.

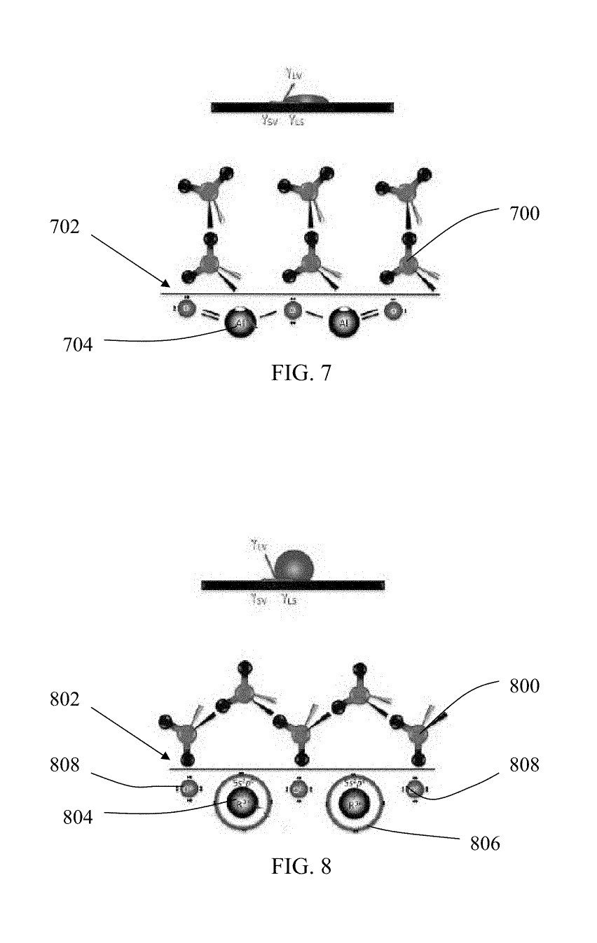

A schematic demonstration of the orientation of a water molecule 700 next to an alumina hydrophilic surface 702 is presented in FIG. 7. Aluminum atoms 704 at the surface 702 are electron deficient, with six electrons in their three “sp² hybrid” orbitals. Therefore, to achieve a full octet of electrons, the aluminum atoms 704 strive to accept a pair of electrons from the water molecules 700 next to the surface. Such a tendency forces the water molecules 700 at the surface 702 to be oriented in such a way that they have three hydrogen bond (HB) vectors pointing towards the surface. Two of these vectors are associated with electron pairs and the other is associated with one of the OH bonds. The fourth FIB vector, which is associated with the other OH bond, is pointing preferentially outward from the surface 702 to the bulk. The depicted water molecule orientation is consistent with results of MD simulations for hydrophilic surfaces.

In the case of rare earth element materials (e.g., rare earth oxides), however, metal atoms have a different chemistry than that of aluminum atoms. In rare earth elements, electrons are being added into the inner 4f orbitals, which are shielded by eight electrons of the (5s²p⁶) outer shell. Therefore, contrary to aluminum atoms, the valance band of rare earth elements has a full octet of electrons, and the empty orbitals, if any, are not accessible to the surrounding environment. Accordingly, it is presently believed rare earth elements have no tendency to either accept or donate electron pairs when in contact with wetting liquids. As a result, unlike other oxide ceramics, rare earth oxides are herein found to be hydrophobic.

Referring to FIG. 8, and without wishing to be bound by any particular theory, it is thought that water molecules 800 in contact with a surface 802 of a rare earth element material (e.g., a rare earth oxide) orientate themselves in such a way that they have one FIB vector, associated with an OH bond, preferentially pointing toward the surface. The remaining three HB vectors preferentially point outward from the surface, thus forming hydrogen bonds with other water molecules in the bulk. Since the 4f orbitals 804 of rare earths are completely shielded by the octet electrons of the outer (5s²p⁶) orbitals 806, they have no tendency to accept or donate pairs of electrons when in contact with water molecules. In various embodiments, additional atoms 808 in the rare earth element material may include oxygen, carbon, nitrogen, fluorine, and/or boron, depending on whether the rare earth element material includes a rare earth oxide, a rare earth carbide, a rare earth nitride, a rare earth fluoride, and/or a rare earth boride, respectively.

### EXAMPLES

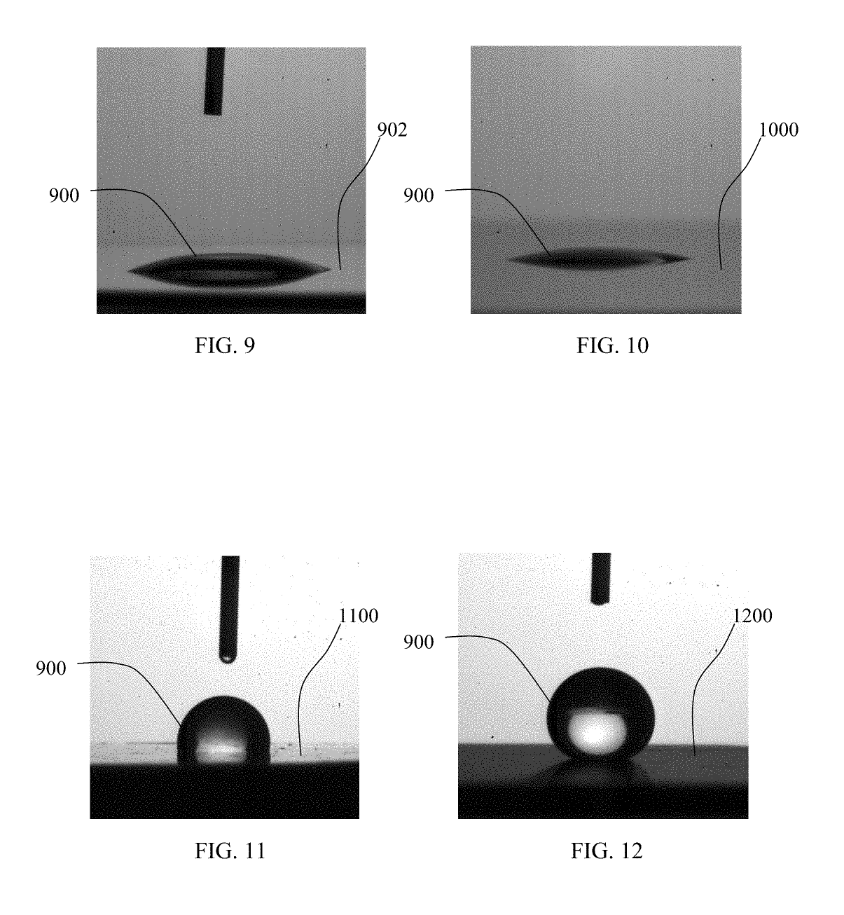

Hydrophobic surfaces were produced by forming a thin coating (between about 200 nm and 350 nm) of a ceramic material containing a rare earth oxide onto both smooth and textured substrates. Wetting measurements indicated that advancing water contact angles of these surfaces ranged from 115° for smooth to 160° for textured substrates. These contact angles are well beyond the water contact angles obtained with common metal oxides, such as alumina (Al₂O₃) and silica (SiO₂), which have water contact angles of about 25-30° and about 15-20°, respectively. FIGS. 9 through 12 depict water droplets 900 resting on the alumina surface 902, the silica surface 1000, the smooth hydrophobic surface 1100, and the textured hydrophobic surface 1200.

As discussed in more detail below, systematic water droplet impingement, water condensation, and thermal stability experiments were performed to characterize the performance of the hydrophobic materials containing a rare earth oxide, described herein. Results from these experiments show the following: (1) the hydrophobic materials are capable of repelling water droplets even when they are deposited on smooth substrates; (2) the hydrophobic materials promote dropwise water condensation with remarkably improved heat transfer coefficients, when tested inside a condensation chamber under simulated industrial conditions; and (3) the nonwetting properties of the hydrophobic materials remained unchanged when the hydrophobic materials were heated to 400° C. for two hours and then cooled down to room temperature. By comparison, other hydrophobic surfaces, such as a surface coated with fluorosilane (FOS), a common hydrophobic surface modifier, did not retain the hydrophobic properties under these conditions.

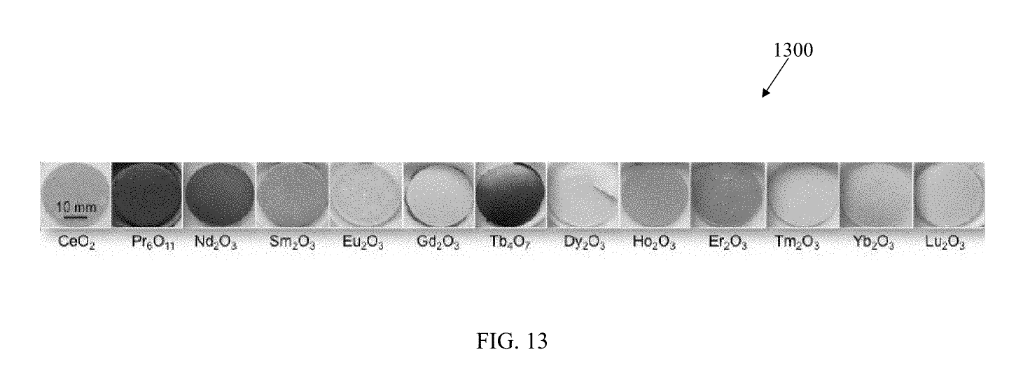

To assess the hydrophobic properties of the rare earth oxide materials described herein, ceramics of oxide powders were synthesized for all the rare earth elements across the lanthanides row, except for promethium oxide because of its radioactive properties. To produce the rare earth oxide ceramics, rare earth oxide powders were dry pressed at a pressure between 30,000 and 50,000 tsi (tons per square inch) in a cylindrical steel press mold, without use of any binding agents or additives. After pressing, the materials were sintered inside a tube furnace under an argon environment. The sintering temperature for each rare earth ceramic was different and estimated based on its melting point (i.e., between 60% and 80% of the melting point of each rare earth oxide). Accordingly, sintering temperatures were from about 1400° C. to about 1650° C. in this work. Photographs of sintered ceramics 1300 are depicted in FIG. 13.

After synthesizing the rare earth oxide ceramic materials, the wetting properties and total surface free energies were quantified through systematic contact angle measurements on the materials using the following three liquids: diiodomethane (DIM), ethylene glycol (EG), and water. These three well-characterized liquids formed the basis of surface free energy calculations utilizing the van Oss-Good-Chaudhury approach. To determine the relationship between the surface polarity and the nonwetting properties of the rare earth oxides, the apolar and polar components of total surface free energy were assessed. The magnitude of the apolar surface free energy was calculated based on measured contact angle data of the apolar liquid, diiodomethane (DIM), and Lifshitz-van der Waals analysis. The polar component, however, was calculated using the contact angle data of polar liquids, i.e., water and ethylene glycol (EG), and simultaneously solving the modified Young equation. Calculation results revealed that the polar component of surface free energy for all the rare earth oxide materials was negligible. This suggests that the surface of these ceramic oxides, contrary to common hydrophilic oxides, have fewer Lewis acid and base sites. Furthermore, results showed no significant variations in the calculated surface free energy of the ceramics across the lanthanides row, which suggests that these ceramics have comparable wetting properties. While not wishing to be bound by any particular theory, the reason for such observation may be attributed to the unique electronic configuration of these materials. For example, the chemical significance of electron addition into inner 4f orbitals that are shielded by overlying 5s2p6 electrons may be so slight that it results in remarkable similarities between the rare earth oxide wetting materials.

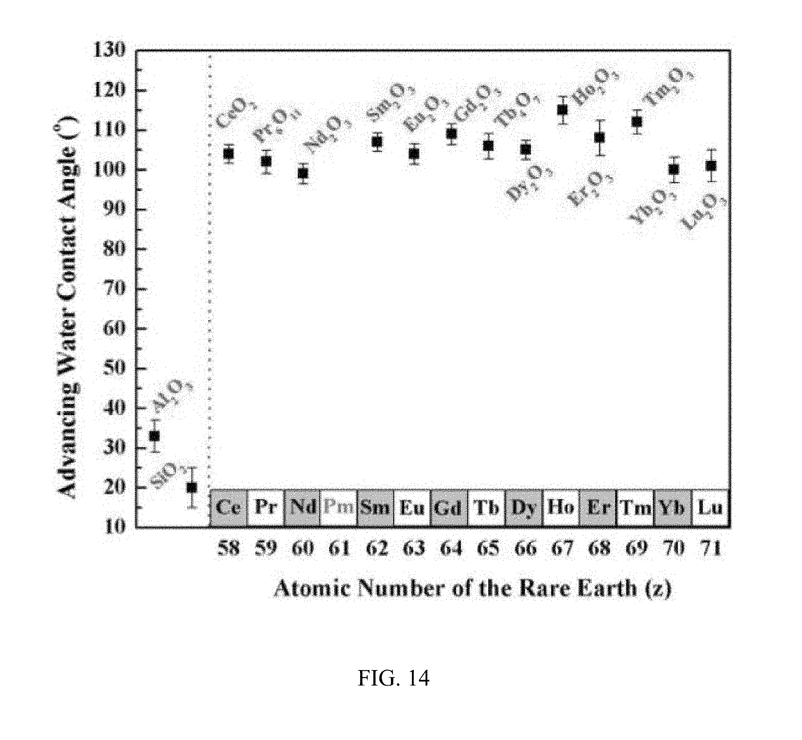

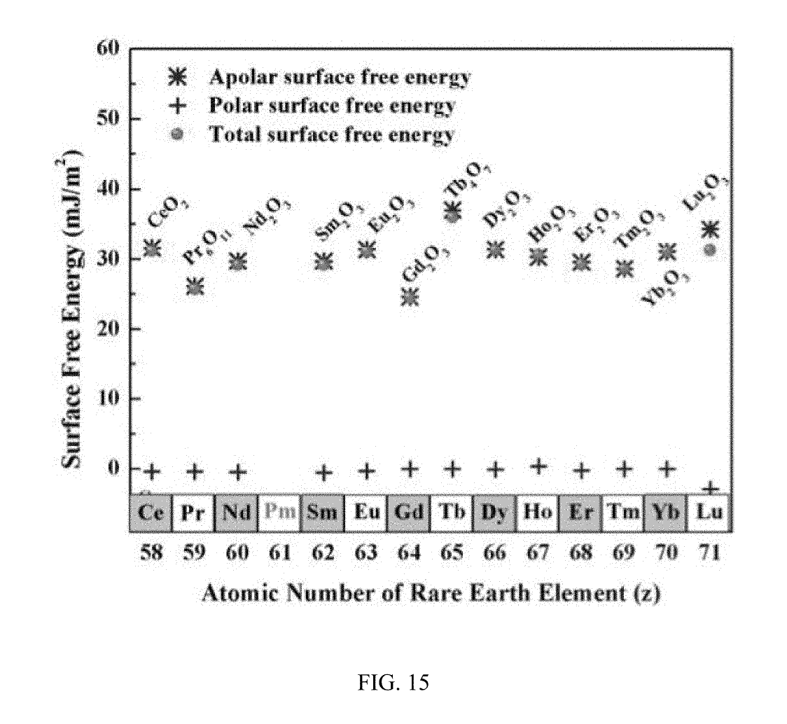

Measured contact angles and surface energies (i.e., calculated total surface free energy and calculated apolar and polar components) for the rare earth oxide materials are illustrated in FIGS. 14 and 15, respectively. As is clear, the intrinsic water contact angle of all test substrates lies between 105° and 115°, which is well beyond the water contact angle of common metal oxides. For example, alumina and silica have water contact angles of about 30° and 20°, respectively. The results in these figures show that the rare earth oxide materials are hydrophobic.

To illustrate potential advantages of the new hydrophobic rare earth oxide materials, described herein, systematic water impingement and water condensation experiments were conducted on surfaces having a thin layer (e.g., layer thickness from about 200 nm to about 350 nm) of a representative rare earth oxide (for example cerium oxide) sputtered on smooth silicon wafers as well as silicon nanograss posts.

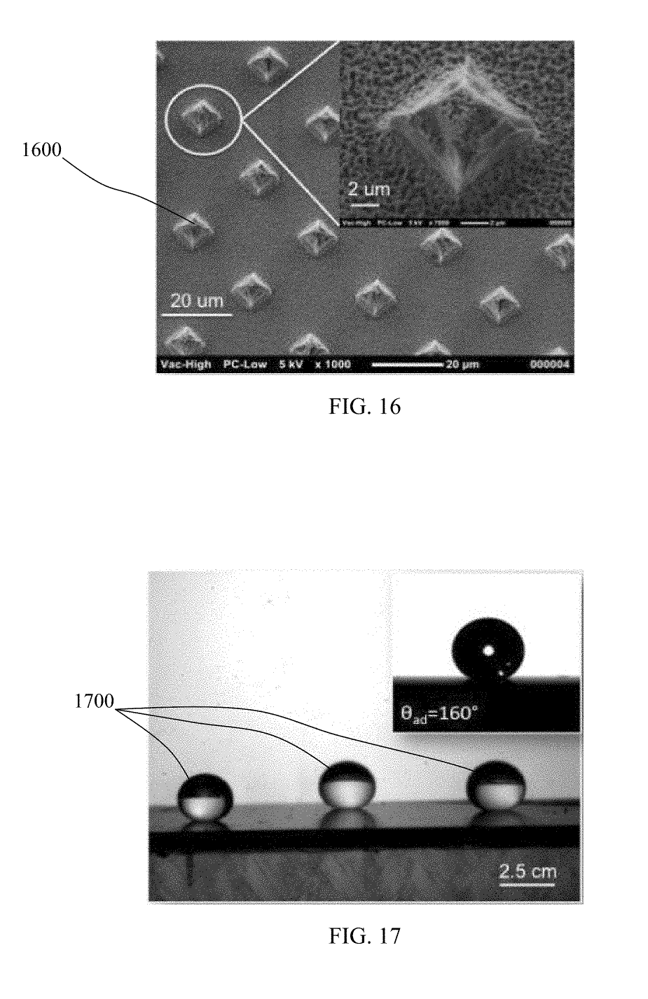

Referring to FIG. 16, silicon nanograss posts 1600 were arranged in square arrays with a width a of about 10 μm, a height h of about 10 μm, and a spacing b from about 5 μm to about 30 μm. To grow the nanograss, posts were placed inside an inductively coupled plasma chamber with a controlled flow of etching gases (i.e., SF₆/O₂). The average width of the grass wires was about 100 nm with spacing of about 100 nm to about 200 nm. The nanograss posts 1600 were then modified for superhydrophobicity with a thin layer of a rare earth oxide through sputtering.

Referring to FIG. 17, wetting measurements of the nanograss posts coated with about 300 nm of cerium oxide (ceria) indicated that water droplets 1700 are in a Cassie state. Advancing and receding water contact angles were measured to be 160° and 155°, respectively.

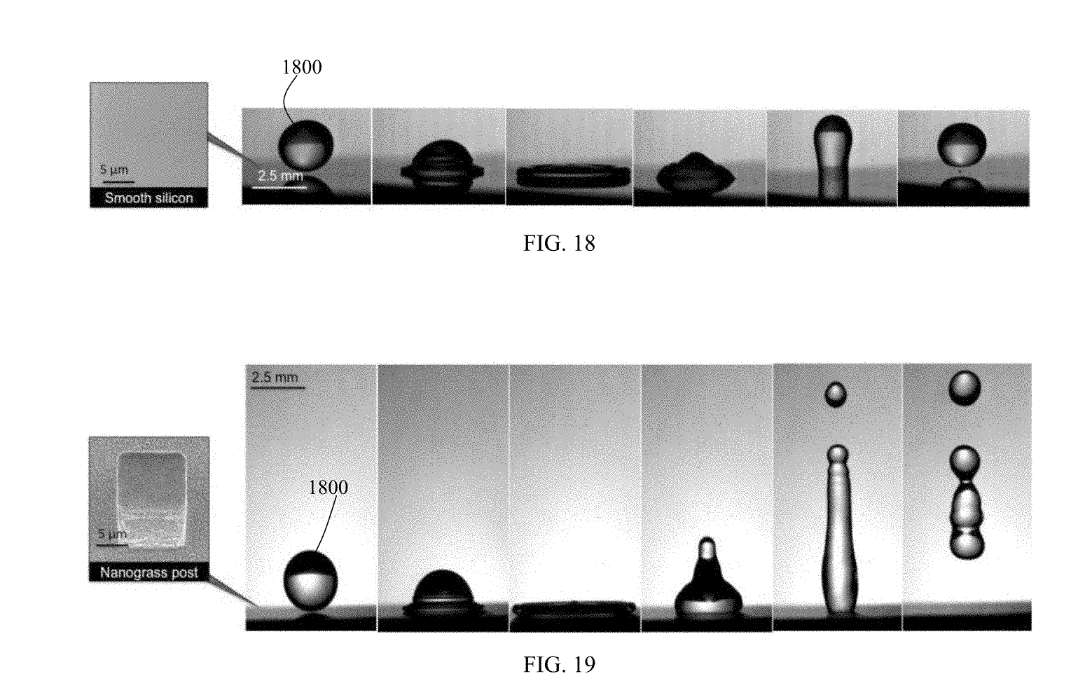

The dynamics of the impingement of water droplets 1800 on the ceria-coated smooth and nanograss post surfaces is depicted in the images of FIGS. 18 and 19, respectively. Water droplet impingement velocity was about 1.2 m/s for the ceria-coated smooth surface (FIG. 18) and about 1.6 m/s for the ceria-coated nanograss post surface (FIG. 19). The results show that both surfaces repelled the water droplets 1800 after impingement. The results were impressive in the sense that water repellency was observed even on smooth ceria-coated surfaces, indicating that this ceramic is intrinsically hydrophobic. Moreover, ceria-coated nanograss silicon posts were capable of repulsing water droplets with relatively high impact velocities (e.g., about 3.7 m/s).

To further demonstrate the industrial implications of the ceramic materials developed herein, systematic water condensation experiments were conducted inside a controlled vacuum condensation chamber, which replicated the condition of a typical industrial condenser. The condensation chamber enabled direct measurement of the heat flux over a wide range of experimental conditions that were analogous hose of real industrial condensers.

For the condensation experiments, hydrophobic test surfaces were fabricated by depositing a thin layer of a representative rare earth oxide on smooth silicon wafers. The rare earth oxides used for the experiment were cerium oxide and erbium oxide. To establish a benchmark, water condensation experiments were also performed on a hydrophilic silicon wafer as well as a hydrophobic silicon wafer that was modified with a thin coating of (1H,1H,2H,2H-fluorooctyl triethoxysilane) fluorosilane (FOS) through vapor phase deposition.

In these experiments, after clamping the wafer to an instrumented copper cooling block within the condensation chamber, saturated steam at a pressure of 75 kPa and a temperature of 92° C. was generated by a 20 kW electric boiler. A water-cooled heat exchanger provided 20 kW of cooling power to the test surface. The heat flux was measured by calculating the temperature gradient along the copper cooling block, and the departing drop sizes were measured from images obtained with a high-resolution video camera. Heat flux was measured for each substrate during the experiment

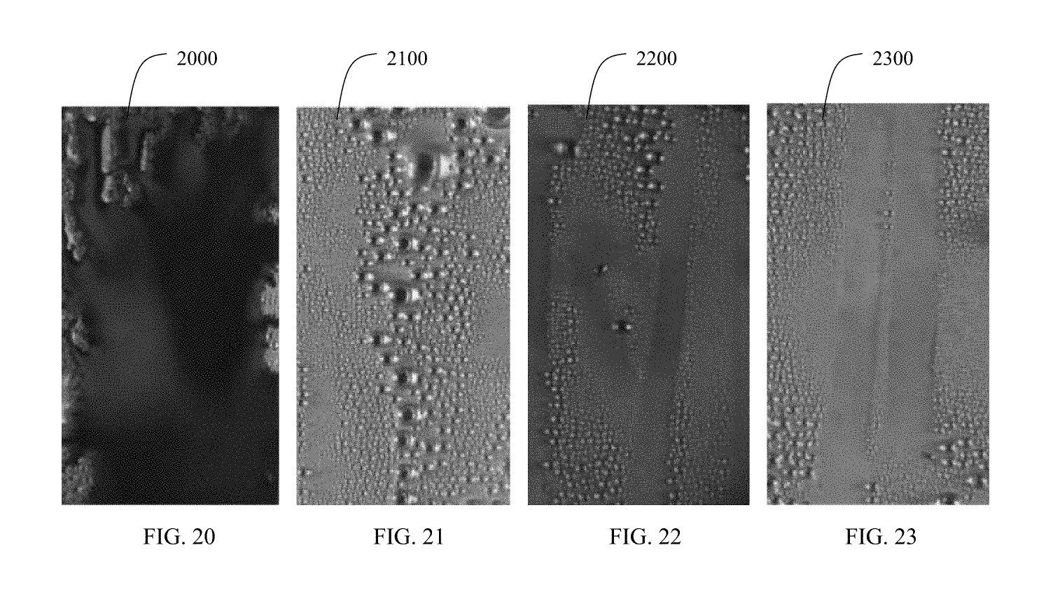

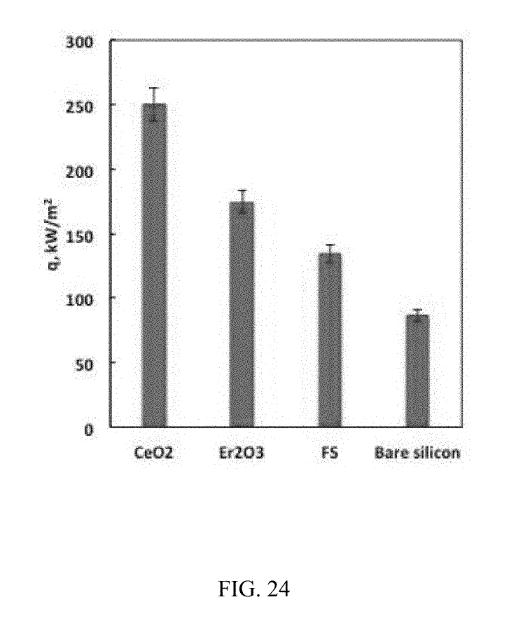

Snapshot images of the dynamics of condensate formation and shedding from test substrates are shown in FIGS. 20 through 23. Referring to FIG. 20, in the case of a bare silicon substrate 2000, which is analogous to other hydrophilic surfaces, filmwise condensation was observed. Specifically, a continuous liquid film formed on the silicon substrate 2000, which led to a significant heat transfer resistance between the steam and the surface, and a subsequent decrease in the measured heat flux, as depicted in the plot of FIG. 24.

Referring to FIGS. 21 through 23, contrary to the filmwise condensation properties of bare silicon, dropwise condensation was observed on a hydrophobic FOS-coated silicon surface 2100 (FIG. 21), a cerium oxide surface 2200 (FIG. 22), and an erbium oxide surface 2300 (FIG. 23). In terms of measured heat flux, however, the rare earth oxide coatings out-performed the state-of-the-art fluorosilane (FOS), which is a common material for surface modifications. As depicted in FIG. 24, the higher heat flux obtained with the rare earth oxide coatings could result in considerably enhanced heat transfer rates in condensation applications.

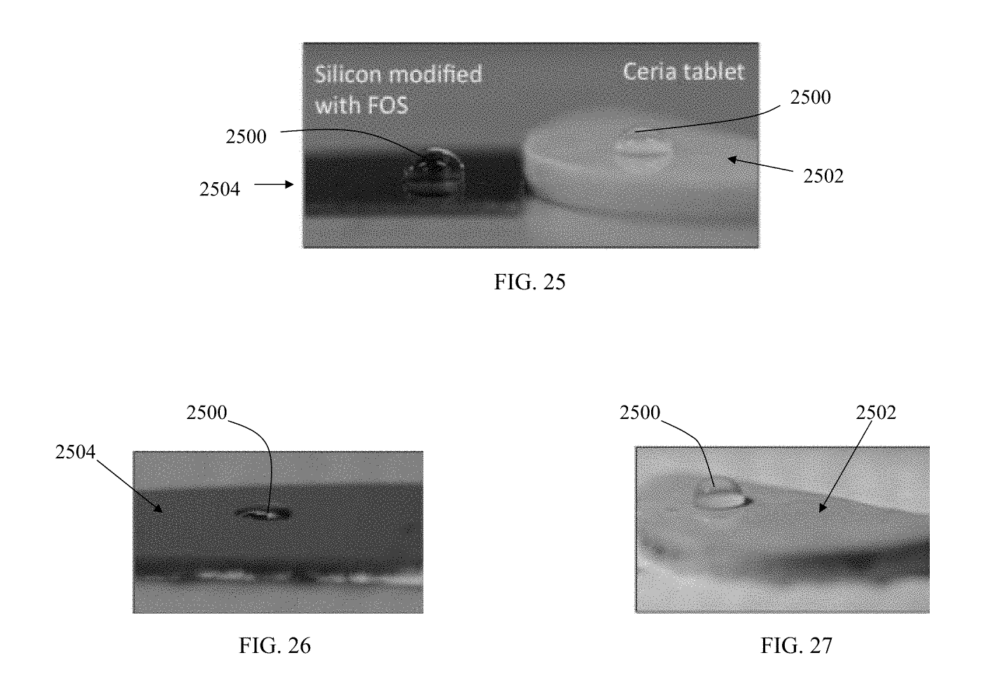

To further demonstrate the robustness of the rare earth oxide materials described herein, the thermal stability of these materials was examined by placing the sintered materials inside a box furnace and heating to 400° C. for 2 hours and then cooling to room temperature. To establish a baseline, a hydrophobic surface consisting of silicon substrates modified with a layer of (1H,1H,2H,2H-fluorooctyl triethoxysilane) fluorosilane (FOS) polymers was also tested under similar conditions. FIG. 25 includes a photograph of water droplets 2500 on a sintered cerium oxide surface 2502 and a fluorosilanized silicon surface 2504 before heating to 400° C. for 2 hours. FIGS. 26 and 27 include photographs of water droplets 2500 on these surfaces 2502, 2504 after heating to 400° C. for 2 hours. As indicated by the water droplets 2500 on these surfaces 2502, 2504 in these figures, although both surfaces 2502, 2504 demonstrated hydrophobic attributes before the test, the sintered rare earth oxide tablet was the only material to possess hydrophobic attributes after the test (i.e., after heating in the furnace). Because FOS is not thermally stable at such high temperature, the FOS sample showed hydrophilic behavior after the test. This experiment further demonstrates that rare earth oxide materials are not only intrinsically hydrophobic, but they are capable of withstanding harsh industrial environments.

The results of the contact angle, water impingement, thermal stability, and condensation experiments, described above, show that the rare earth oxide materials are intrinsically hydrophobic and robust. In addition to conformal coating, in certain embodiments, the rare earth oxides (or other rare earth element materials) are incorporated into other engineered materials and structures to achieve enhanced attributes. Examples include ceramics doped with rare earth oxides, metals doped with rare earths oxides, and polymer composites having rare earth oxides. Moreover, doping a rare earth oxide with another rare earth oxide may result in improved properties. For example, in one embodiment, a light rare earth oxide (e.g., ceria) is doped with a heavy rare earth oxide (e.g., gadolinium oxide).

Examples with an Intermediate Layer Including Titanium

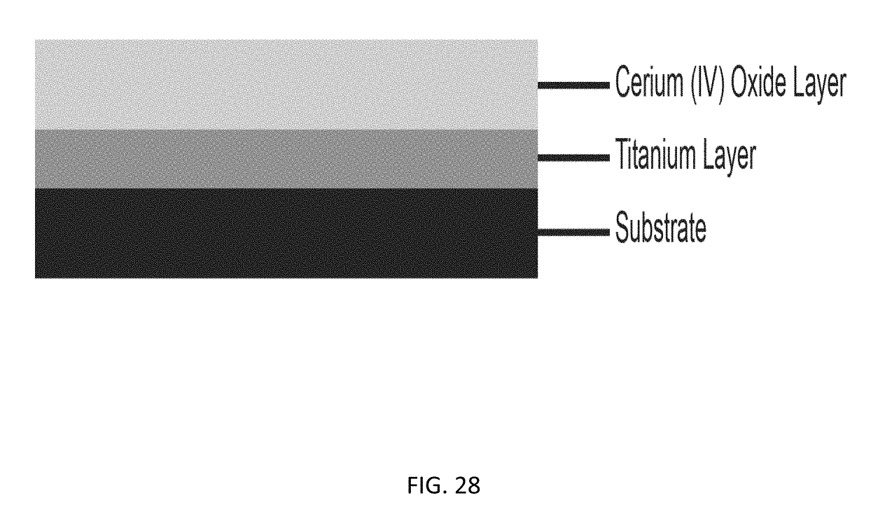

A 10-100 nm layer of titanium (pure) was sputter-deposited on a silicon substrate. Further on this titanium layer, a 10-300 nm layer of ceria was sputter-deposited. In further examples, a 10-300 nm layer of erbia was sputter-deposited. Various experiments were conducted with varied thicknesses of the titanium layer and the ceria layer or erbia layer. FIG. 28 shows a cross-sectional view schematic of an article where a ceria (cerium oxide (IV)) layer was sputter-deposited on top of a titanium layer, which was sputter-deposited on top of a silicon substrate.

In order to test the resilience of silicon substrate wafers coated with the films as shown above in FIG. 28 and the substrate wafers coated with a titanium layer and the erbia layer on top of the titanium layer, these wafers were subjected to two harsh process conditions: steam treatment and boiling, both for a period of one hour. In order to provide a comparison, ceria films deposited on the same silicon substrate wafers in the absence of the titanium layer were also studied.

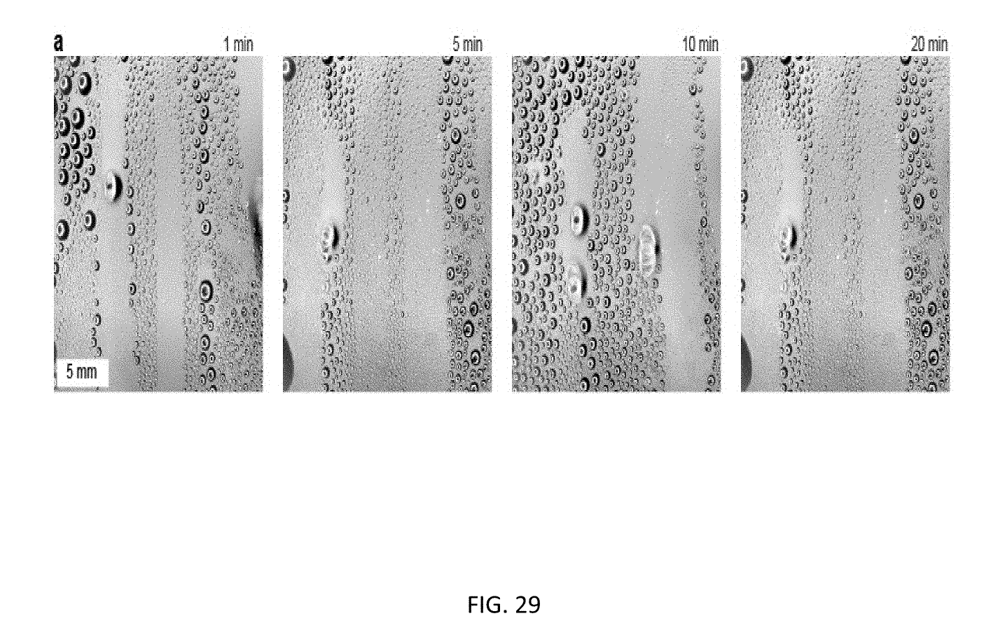

Systematic steam treatment (water condensation) experiments were conducted inside a controlled vacuum condensation chamber, which replicates the condition of a typical industrial condenser. This condensation chamber enables direct measurement of the heat flux over a wide range of experimental conditions, analogous to those of real industrial condensers. After clamping the wafer to an instrumented copper cooling block within the condensation chamber, saturated steam at a pressure of 75 kPa and temperature of 92° C. was generated by a 20 kW electric boiler. A water-cooled heat exchanger provided 20 kW of cooling power to the test surface. The heat flux was measured by calculating the temperature gradient along the copper-cooling block, and the departing drop sizes were measured from images obtained with a high-resolution video camera. The heat transfer coefficient was measured to be 60 kW/m²K, which is about fifteen-fold higher than that of film-wise condensation. Photographs of the dynamics of condensate formation are shown in FIG. 29.

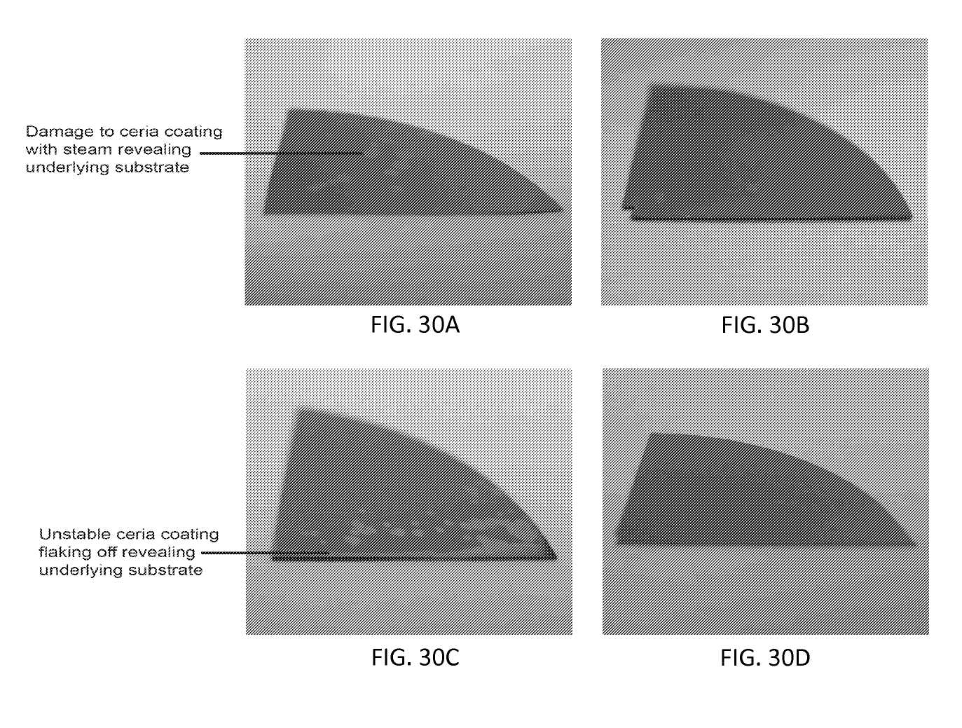

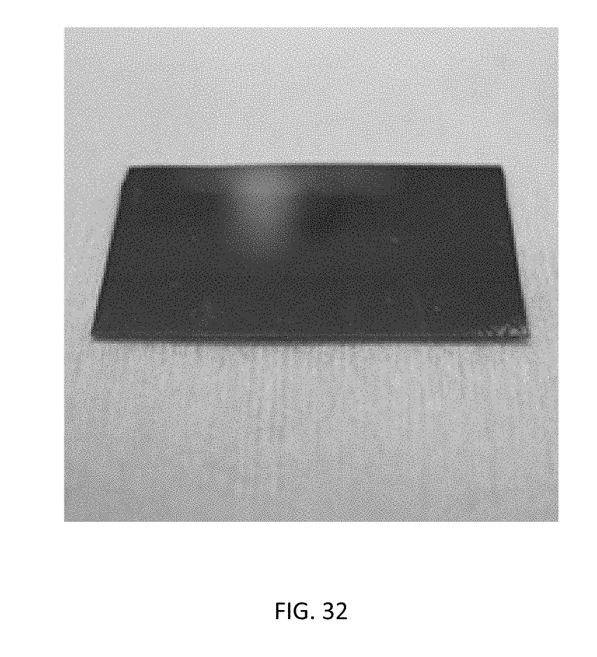

Furthermore, as seen FIG. 30a, steam treatment caused damage to the ceria coating deposited in the absence of a titanium layer, thereby revealing the underlying substrate, which is undesirable. However, as seen in FIG. 30b, ceria in the presence of the titanium adhesion layer did not degrade despite the steam treatment. In fact, the ceria layer did not wear off even after 10 hours of continuous steam treatment as shown in FIG. 32. The presence of the titanium adhesion layer allowed for the ceria layer to remain stably adhered to the substrate.

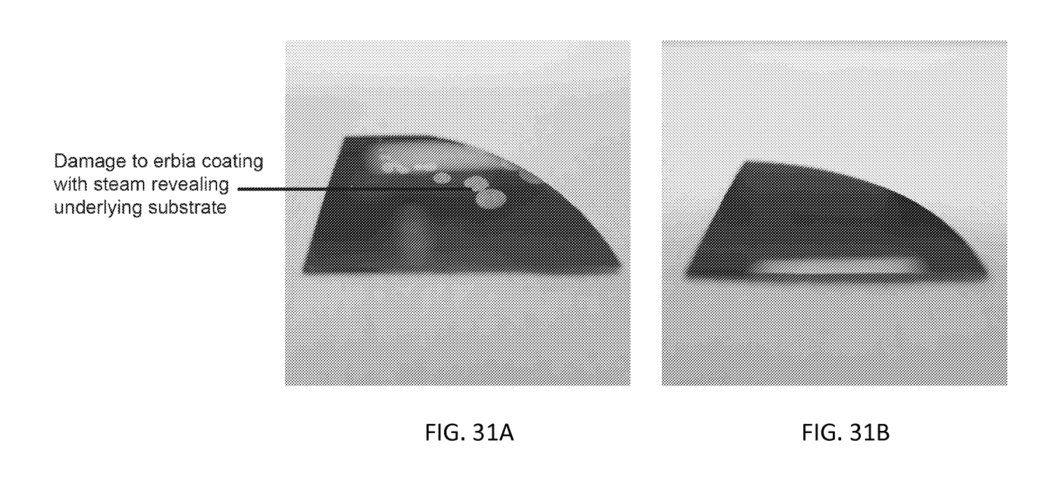

Furthermore, as seen in FIG. 31a, steam treatment caused damage to the erbia coating deposited in the absence of a titanium layer, thereby revealing the underlying substrate, which is undesirable. However, as seen in FIG. 31b, erbia in the presence of the titanium adhesion layer did not degrade despite the continuous steam treatment.

The sample was then immersed in a 250 ml beaker containing boiling water maintained at 100° C. for one hour. Similar damage and flaking was observed for the ceria coating in the absence of the titanium layer with the boiling water treatment, as seen in FIG. 30c. However, in contrast, the ceria films coated on the titanium adhesion layer showed superior resilience with no visual signs of damage to the coating after treatment with steam or boiling water, as seen in FIGS. 30b and d, respectively.

The experiments above demonstrate that the presence of the intermediate layer comprising titanium improves longevity of rare earth material (e.g., rare earth oxide) coatings. In addition to conformal coating, in certain embodiments, the rare earth oxides (or other rare earth element materials) are incorporated into other engineered materials and structures to achieve enhanced attributes. Examples include ceramics doped with rare earth oxides, metals doped with rare earths oxides, and polymer composites having rare earth oxides. Moreover, doping a rare earth oxide with another rare earth oxide may result in improved properties. For example, in one embodiment, a light rare earth oxide (e.g., ceria) is doped with a heavy rare earth oxide (e.g., gadolinium oxide).

When deposited on a titanium layer on any substrate, ceria films are robust and can withstand saturated steam and boiling water for as long as 10 hours without degrading. The presence of an intermediate titanium layer can improve the adhesion of all rare earth oxides to any substrate in particular metallic substrates such as stainless steel and copper that are widely used in industrial applications. Such a layered material has excellent far-reaching applications such as reducing corrosion, scaling and bio-fouling in the hydropower and marine industries.

### Equivalents

While the invention has been particularly shown and described with reference to specific preferred embodiments, it should be understood by those skilled in the art that various changes in form and detail may be made therein without departing from the spirit and scope of the invention as defined by the appended claims.

What is claimed is:

1. An article comprising:
a base substrate;
an intermediate layer on the base substrate, wherein the intermediate layer comprises at least one element or compound selected from the list comprising titanium, chromium, indium, zirconium, tungsten, and titanium nitride; and
a hydrophobic layer on the intermediate layer, the hydrophobic layer comprising a rare earth element material.

2. The article of claim 1, wherein the rare earth element material is or comprises rare earth oxide or a lanthanide series rare earth oxide.

3. The article of claim 2, wherein the rare earth oxide is or comprises cerium (IV) oxide (“ceria”).

4. The article of any claim 1, wherein the intermediate layer is or comprises titanium.

5. The article of claim 4, wherein the titanium is pure titanium.

6. The article of claim 4, wherein the titanium is a titanium alloy.

7. The article of claim 4, wherein the titanium is doped with a second material.

8. The article of claim 1, wherein an exposed surface of the article has a dynamic contact angle with water of at least about 90 degrees.

9. The article of claim 1, wherein the rare earth element material comprises at least one member selected from the group consisting of a rare earth oxide, a rare earth carbide, a rare earth nitride, a rare earth fluoride, and a rare earth boride.

10. The article of claim 1, wherein the rare earth element material comprises a combination of one or more species within one or more of the following categories of compounds: a rare earth oxide, a rare earth carbide, a rare earth nitride, a rare earth fluoride, and a rare earth boride.

11. The article of claim 1, wherein the base substrate comprises a metal.

12. The article of claim 11, wherein the metal comprises at least one species selected from the list comprising copper, steel, nickel, aluminum, and their alloys.

13. The article of claim 1, wherein the base substrate comprises a ceramic.

14. The article of claim 13, wherein the ceramic comprises at least one species selected from aluminum oxide, aluminum nitride, boron oxide, boron nitride, boron carbide, titanium oxide, titanium nitride, titanium carbide, and any combination thereof.

15. The article of claim 14, wherein the ceramic comprises a metal oxide, a metal carbide, or a metal nitride.

16. The article of claim 1, wherein the base substrate comprises silicon.

17. The article of claim 1, wherein a thickness of the intermediate layer is from about 1 nm to about 1 micron and wherein a thickness of the hydrophobic layer is from about 1 nm to about 1 micron.

18. The article of claim 1, wherein the hydrophobic layer comprises at least about 10 weight percent rare earth element material.

19. The article of claim 1, wherein an exposed surface of the article comprising the hydrophobic layer is textured or wherein the base substrate is textured.

20. The article of claim 19, wherein the exposed textured surface comprises multiplescale surface roughness.

21. The article of claim 1, wherein the hydrophobic layer comprises at least one of a ceramic, a metal, and a polymer.

22. The article of claim 1, wherein the hydrophobic layer is doped with the rare earth element material.

23. The article of claim 1, wherein the rare earth element material comprises a first rare earth oxide doped with a second rare earth oxide.

24. The article of claim 23, wherein the first rare earth oxide is a light rare earth oxide and the second rare earth oxide is a heavy rare earth oxide.

25-36. (canceled)

37. A method of manufacturing and/or retrofitting a hydrophobic article, the method comprising:
providing a substrate material;
depositing an intermediate layer comprising at least one element or compound selected from the list
comprising titanium, chromium, indium, zirconium, tungsten, and titanium nitride on the substrate material; and
depositing a hydrophobic layer comprising a rare earth element material on the intermediate layer.

38-40. (canceled)

41. An article comprising:
a base substrate;
an intermediate layer on the base substrate; and
a hydrophobic layer on the intermediate layer, the hydrophobic layer comprising a rare earth element material, wherein the intermediate layer allows for a loss of less than 5% of the hydrophobic layer when (i) exposed to steam at 92° C. at a pressure of 75 kPa inside a vacuum condensation chamber for 10 hours or (ii) immersed in boiling water for a period of 10 hours.

42. The article of claim 41, wherein the intermediate layer comprises at least one element or compound selected from the list comprising titanium, chromium, indium, zirconium, tungsten, and titanium nitride
